(19) United States
(12) Patent Application Publication
(10) Pub. No.: US 2022/0190524 A1
(43) Pub. Date: Jun. 16, 2022

(54) CABLE AND NOTIFICATION METHOD

(71) Applicant: SONY GROUP CORPORATION, TOKYO (JP)

(72) Inventor: TAKEKI IKEYA, TOKYO (JP)

(21) Appl. No.: 17/593,170

(22) PCT Filed: Feb. 4, 2020
(86) PCT No.: PCT/JP2020/004124

§ 371 Date: Sep. 10, 2021

(30) Foreign Application Priority Data
Mar. 28, 2019 (JP) 2019-063856

(51) Int. Cl. H01R 13/641; G01R 31/50; H01R 13/66

(52) U.S. Cl. CPC H01R 13/641; H01R 13/6683; G01R 31/50

(57) ABSTRACT

An improvement in efficiency of connection work of a cable is achieved. For that purpose, a cable according to the present technique includes: a first connector unit; a second connector unit; a transmission line that has one end connected to the first connector unit and the other end connected to the second connector unit; a control unit that detects connection states of the first connector unit and the second connector unit; an operation detection unit that detects an operation on any one connector unit of the first connector unit and the second connector unit; and a notification unit that performs a notification in accordance with the connection state of the other connector unit in accordance with detection results of the operation detection unit. By providing appropriate notifications, an improvement in efficiency of connection work of a cable is achieved.

### TECHNICAL FIELD

The present technique relates to a technical field regarding a cable connected to a device and a notification method. In particular, it relates to a cable provided with a notification unit that gives a notification of a connection state of the cable.

### BACKGROUND ART

It is important that a cable that connects devices to each other is connected correctly. For example, in a case in which an operation of connecting specific devices to each other is performed in a situation in which a large number of devices are stacked in a rack, the number of cables also increases, and thus it becomes difficult to make correct connections.

PTL 1 discloses a technique relating to a communication cable capable of recognizing connectors of the same communication line.

### CITATION LIST

### Patent Literature

### [PTL 1]

JP 2014-126433A

### SUMMARY

### Technical Problem

However, with the above technique, it was possible to identify a connector and another connector paired therewith on the other end side of the same cable, but it was not possible to ascertain a connection state of the connector on the other end side.

Accordingly, an object of the present technique is to improve efficiency of connection work by giving a notification of connection states of connectors of the same cable.

### Solution to Problem

A cable according to the present technique includes: a first connector unit; a second connector unit; a transmission line that has one end connected to the first connector unit and the other end connected to the second connector unit; a control unit that detects connection states of the first connector unit and the second connector unit; an operation detection unit that detects an operation on any one connector unit of the first connector unit and the second connector unit; and a notification unit that performs a notification in accordance with the connection state of either one of the connector unit of the first connector unit or the second connector unit.

A connection state of a connector unit is, for example, a distinction of whether the connector unit has been connected to a device that is a connection target (a connection target device) (connection determination) or not (non-connection determination). In order to give a notification of the connection state, the cable according to the present technique deals with information (connection information) for specifying the connection state. The information may be, for example, detection signals or information obtained by a determination process. Information about the connection state of each connector unit transmitted and received between the connector units is also referred to as “connection information”.

By providing the notification unit for giving a notification of the connection state of the connector unit, an operator can correctly recognize a state of the cable.

For the operation detection unit, for example, a mechanical switch, a proximity sensor, a contact sensor, or the like is used. By providing the operation detection unit, an operation of the operator on the cable (or connector unit) is detected.

The control unit in the cable described above may include a first connection detection unit that is provided in the first connector unit and detects the connection state of the first connector unit, and a second connection detection unit that is provided in the second connector unit and detects the connection state of the second connector unit.

By providing the first connection detection unit that detects whether or not the first connector unit is connected to a device, it is possible to correctly ascertain the connection state of the first connector unit. Further, it is also possible to give a notification of the second connector unit of the connection state of the first connector unit via the transmission line.

In the cable described above, as the operation detection unit, a first operation detection unit provided in the first connector unit and a second operation detection unit provided in the second connector unit may be provided.

That is, the operation detection unit is provided in each of the first connector unit and the second connector unit.

In the cable described above, the first operation detection unit may detect an operation on the first connector unit, and the second operation detection unit may detect an operation on the second connector unit.

An operated connector unit can be detected by the respective operation detection units provided in the respective connector units.

In the cable described above, in response to the event that any one operation detection unit of the first operation detection unit and the second operation detection unit has performed an operation detection, the notification unit may perform a notification in accordance with the connection state of the connector unit provided with the other operation detection unit.

That is, in a case in which the first operation detection unit has performed an operation detection in response to the event that the operator has performed an operation on the first connector unit, a notification of the connection state of the second connector unit is performed.

In the cable described above, as the notification unit, a first notification unit provided in the first connector unit and a second notification unit provided in the second connector unit may be provided.

That is, the notification unit is provided in each of the connector units.

In the cable described above, the first connector unit may be provided with the first operation detection unit, and the second connector unit may be provided with the second operation detection unit, the first notification unit may perform a notification in accordance with the connection state of the second connector unit in response to the event that the first operation detection unit has performed an operation detection, and the second notification unit may perform a notification in accordance with the connection state of the first connector unit in response to the event that the second operation detection unit has performed an operation detection.

That is, for the operator who is in a state in which an operation on the first connector unit is possible, the connection state of the second connector unit on the other end side can be checked from the first notification unit provided in the first connector unit.

In the cable described above, the notification unit may perform a notification according to a first mode in a case in which both of the first connector unit and the second connector unit are connected to devices and perform a notification according to a second mode in a case in which only one connector unit of the first connector unit and the second connector unit is connected to a device.

That is, a notification mode performed by the notification unit differs depending on whether or not both ends are connected.

In the cable described above, the notification unit may perform a notification in accordance with a communication speed in communication of information performed via the transmission line in a case in which both of the first connector unit and the second connector unit are connected to devices.

That is, by connecting the connector units at both ends to the device, information other than the connection states is notified in a state in which the communication of information via the transmission line is possible.

In the cable described above, the notification unit may perform a notification in accordance with a charge amount of a charging target device in a case in which any one connector unit of the first connector unit and the second connector unit is connected to a charging device and the other connector unit is connected to the charging target device.

The charge amount indicates, for example, a proportion of a remaining amount of battery of the charging target device. In a state in which the charging target device and the charging device are correctly connected with each other, the notification in accordance with the charge amount is performed to the operator.

The above-mentioned cable may include a first light receiving unit provided in the first connector unit, and in a case in which the second connector unit is connected to a device and the first operation detection unit has detected an operation, the notification unit may perform a notification in accordance with whether or not the first light receiving unit has received light having a specific wavelength.

For example, in the device to which the cable is connected, in a case in which a light emitting unit that emits light having a specific wavelength is provided in the vicinity of a place at which the cable is to be connected, the notification unit may perform a notification in response to the event that the light having a specific wavelength has been received with a certain intensity or higher when the operator brings the first connector unit of the cable closer to the device.

In the cable described above, the specific wavelength may be a wavelength corresponding to a type of connector.

By changing the specific wavelength for each type of connector, it is possible to provide a light emitting unit that emits light having a specific wavelength corresponding to each connection place of each type of connector.

The cable described above may include a first sound output unit provided in the first connector unit, and in a case in which the second connector unit is connected to a device and the first operation detection unit has detected an operation, the first sound output unit may output a sound for guiding the first connector unit to a connection part.

By making the specific wavelength different for each type of connector, it is possible to specify the place at which the cable is to be connected. Further, by providing the first voice output unit, voice guidance is performed even when connection work of the cable is performed in a state in which the vicinity is not visible.

The cable described above may include a first sound output unit provided in the first connector unit, and the first sound output unit may output a third sound in a case in which the first connector unit comes closer to another connection part than to a target connection part.

That is, the first sound output unit notifies information about whether or not the first connector unit is approaching a correct connection place.

The cable described above may include a first sound output unit provided in the first connector unit, and the first sound output unit may output a second sound in a case in which the first connector unit is connected to a target connection part.

As a result, information about whether or not the connection is correct may be notified to the operator using a success sound in a case in which the first connector unit is connected to the device.

In the cable described above, the notification unit may perform a notification in a case in which the first connector unit is connected to the device and the first light receiving unit receives light.

As a result, it is possible to prevent the notification from being indiscriminately performed before the first connector unit is connected to the device.

In the cable described above, the notification unit may be a notification light emitting unit, and the notification may be performed using light emission of the notification light emitting unit.

As a result, the connection states of the connectors are notified using the light emission.

In the cable described above, the notification unit may have a sound output unit, and the notification may be performed using a sound output generated by the sound output unit.

As a result, the connection states of the connectors are notified using sound.

A notification method of the present technique is a method comprising, in a cable including: a first connector unit; a second connector unit; a transmission line that has one end connected to the first connector unit and the other end connected to the second connector unit; a control unit that detects connection states of the first connector unit and the second connector unit; and an operation detection unit that detects an operation on any one connector unit of the first connector unit and the second connector unit, performing a notification in accordance with a connection state of the other connector unit in accordance with detection results of the operation detection unit.

### BRIEF DESCRIPTION OF DRAWINGS

FIG. 1 is a perspective view showing a cable and devices according to an embodiment of the present technique.

FIG. 2 is a perspective view of the cable.

FIG. 3 is a block diagram of the cable.

FIG. 4 is a diagram for explaining an example of an operation detection unit.

FIG. 5 is a diagram for explaining an example of a notification unit.

FIG. 6 is a diagram for explaining another example of the notification unit.

FIG. 7 is a perspective view for explaining a first notification mode.

FIG. 8 is a schematic diagram for explaining the first notification mode.

FIG. 9 is a schematic diagram for explaining a second notification mode.

FIG. 10 is a schematic diagram for explaining a third notification mode.

FIG. 11 is a schematic diagram for explaining a fourth notification mode.

FIG. 12 is a schematic diagram for explaining a fifth notification mode.

FIG. 13 is a diagram for explaining an example of a lighting pattern.

FIG. 14 is a schematic diagram for explaining a sixth notification mode.

FIG. 15 is a block diagram of the cable in the fifth notification mode or the sixth notification mode.

FIG. 16 is a flowchart for implementing the first to sixth notification modes.

FIG. 17 is a perspective view of a cable and a device according to a second embodiment.

FIG. 18 is a block diagram of the cable according to the second embodiment.

FIG. 19 is a schematic diagram for explaining a notification mode in the second embodiment.

FIG. 20 is a block diagram of the device according to the second embodiment.

FIG. 21 is a flowchart for implementing a seventh notification mode in the second embodiment.

FIG. 22 is a flowchart for implementing an eighth notification mode in the second embodiment.

FIG. 23 is a diagram schematically showing an overall configuration of an operating room system.

FIG. 24 is a diagram showing a display example of an operation screen on a centralized operation panel.

FIG. 25 is a diagram showing an example of a state of an operation to which the operating room system is applied.

FIG. 26 is a block diagram showing an example of a functional configuration of a camera head and a camera control unit (CCU) shown in FIG. 24.

### DESCRIPTION OF EMBODIMENTS

Hereinafter, embodiments will be described in the following order with reference to the accompanying drawings.

<1. Configurations of cable and device>
<2. Examples of notification mode>
<2-1. First notification mode>
<2-2. Second notification mode>
<2-3. Third notification mode>
<2-4. Fourth notification mode>
<2-5. Fifth notification mode>
<2-6. Sixth notification mode>
<3. Flowchart in first to sixth notification modes>
<4. Second embodiment>
<4-1. Seventh notification mode>
<4-2. Flowchart in seventh notification mode>
<4-3. Eighth notification mode>
<4-4. Flowchart in eighth notification mode>
<5. Modified examples>

### <6. Summary>

<7. Application examples>
<8. Present technique>

### <1. Configurations of Cable and Device>

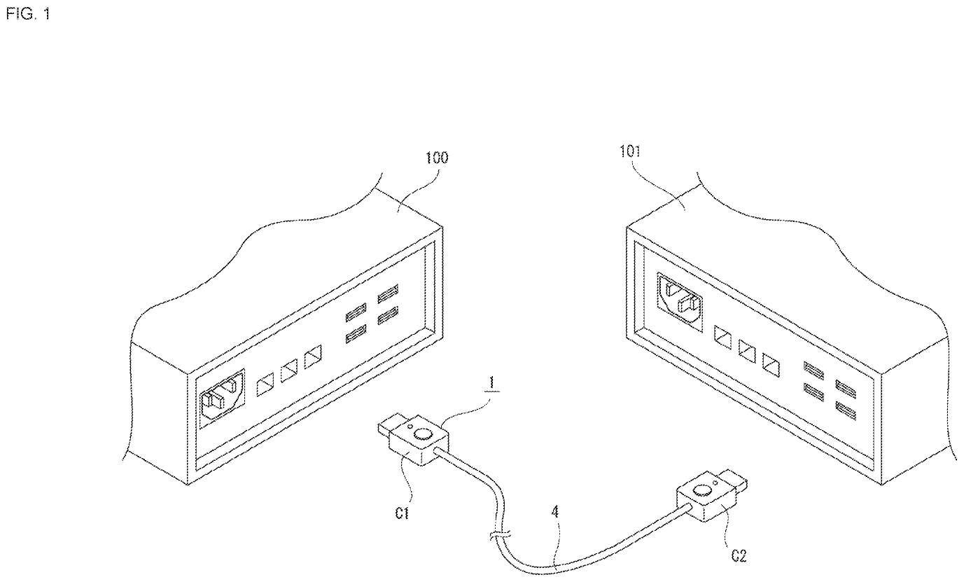

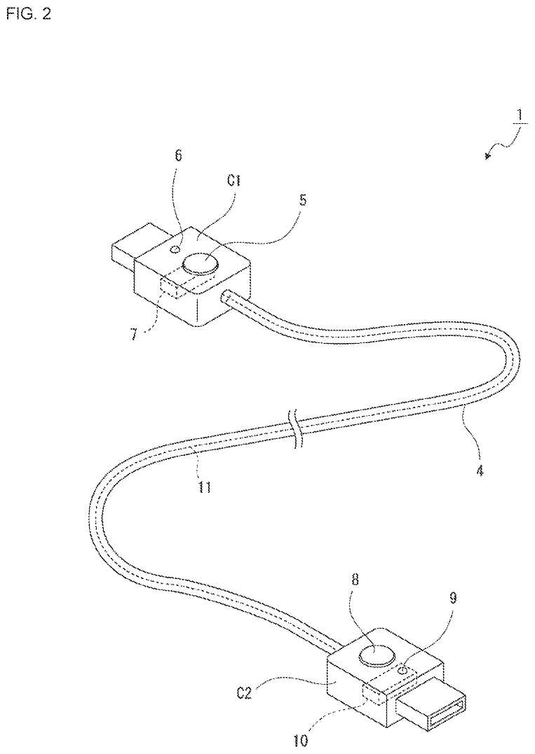

With reference to FIGS. 1 and 2, configurations of a cable 1 and devices 100 and 101 to which the cable 1 of the present embodiment is connected will be described.

The cable 1 is a cable for forming a wired transmission path for signals or power between devices.

The cable 1 is, for example, an audio cable, a video cable, a communication cable such as a local area network (LAN) cable or a universal serial bus (USB) cable, a charging cable for charging a device, or the like. That is, the cable 1 may be provided with a transmission line for connecting two connector units provided at both ends thereof.

The device 100 and the device 101 are assumed to be various devices such as audio devices, video devices, communication devices, and information processing devices such as personal computers.

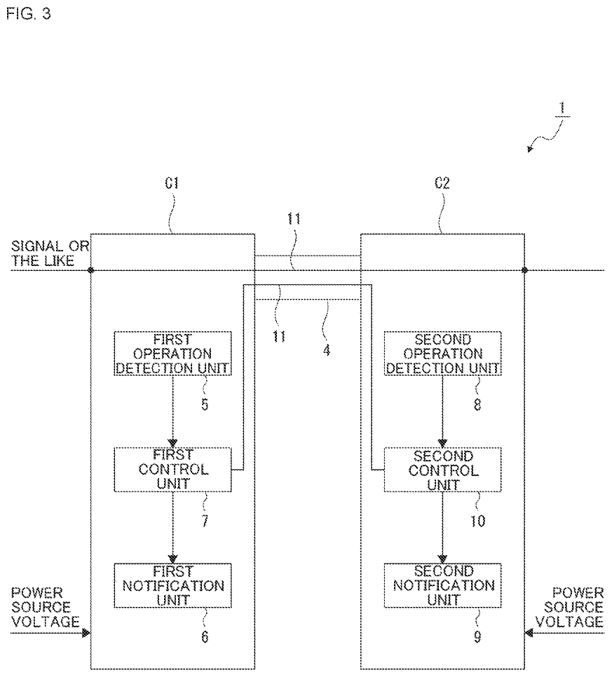

As shown in FIGS. 2 and 3, the cable 1 includes a first connector unit C1, a second connector unit C2, and a cable unit 4. Also, although the first connector unit C1 and the second connector unit C2 have the same shape in FIG. 2, shapes of the connectors may be different from each other.

FIG. 3 is a block diagram of the first connector unit C1 and the second connector unit C2.

The first connector unit C1 includes a first operation detection unit 5 servings as an operation detection unit, a first notification unit 6, and a first control unit 7.

The second connector unit C2 includes a second operation detection unit 8 serving as an operation detection unit, a second notification unit 9, and a second control unit 10.

The cable unit 4 has one or a plurality of transmission lines 11 connecting a terminal of the first connector unit C1 with a terminal of the second connector unit C2 therein.

At least one of the transmission lines 11 is used for transmitting information from one device to the other device and supplying a drive voltage to the other device.

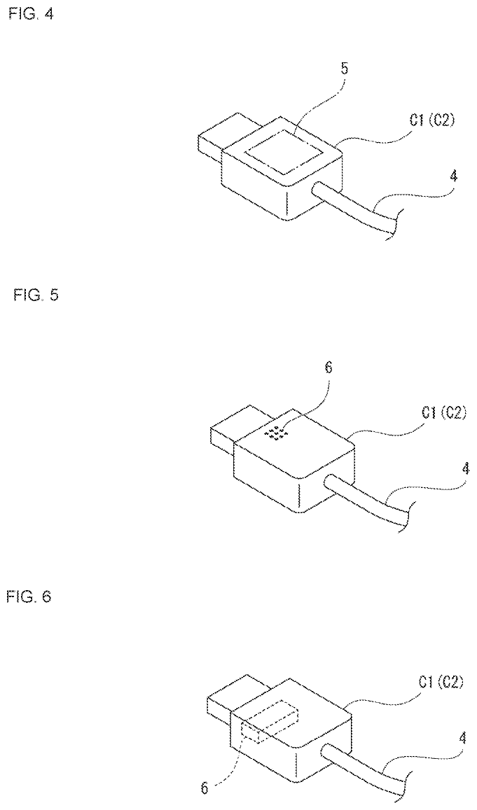

The first operation detection unit 5 and the second operation detection unit 8 detect an operation of an operator, who performs connection work of the cable 1, on a connector unit (the first connector unit C1 or the second connector unit C2). As the first operation detection unit 5 and the second operation detection unit 8, for example, an operation switch using a mechanical switch, a contact sensor for detecting touching by an operator (see FIG. 4), a proximity sensor for detecting approach of the operator's hand or the like (see FIG. 4), or the like can be adopted. Also, the cable 1 shown in FIG. 2 shows an example in which operation switches are provided as the first operation detection unit 5 and the second operation detection unit 8.

The first notification unit 6 and the second notification unit 9 are provided to notify the operator of the connection states of the connector units. A connection state is a distinction of whether a connector unit is connected to a device that is a connection target (a connection target device) (connection determination) or not (non-connection determination).

As the first notification unit 6 and the second notification unit 9, for example, notification light emitting units that perform a notification in accordance with the connection states of the connector units by emitting light, sound output units that perform a notification in accordance with the connection states of the connector units by outputting a sound (see FIG. 5), vibration generation units that vibrate the connector units (see FIG. 6), or the like can be adopted.

Also, the cable 1 shown in FIG. 2 shows an example in which notification light emitting units are provided as the first notification unit 6 and the second notification unit 9.

The first control unit 7 performs detection of whether or not the first connector unit C1 is connected to the device 100. That is, it detects the connection state of the first connector unit C1. Information used by the first control unit 7 for the detection is described as “connection information”.

For example, in the first connector unit C1, in a case in which there is a predetermined terminal whose terminal state (for example, a high potential (H), a low potential (L), and high impedance) changes depending on presence or absence of connection with the device 100, the first control unit 7 monitors the terminal state of the predetermined terminal, and thus it is possible to detect whether or not the first connector unit C1 is connected to the device 100. That is, detection of a signal indicating whether or not the first connector unit C1 and the device 100 are connected with each other is performed. In this case, information about the terminal state is used as the connection information.

In addition, the first control unit 7 can be configured to detect, using an optical sensor, a state in which a terminal portion of the first connector unit C1 is closed (that is, a state in which it is connected to the device 100) and a state in which the terminal portion is open (that is, a state in which it is not connected to the device 100).

Further, the first control unit 7 may be configured to detect the connection state using a mechanical switch whose state changes depending on presence or absence of the connection with the device 100.

Alternatively, by receiving a connection detection signal from the device 100, connection of the first connector unit C1 to the device 100 may be able to be detected.

These forms for detecting the connection state of the connector unit are just examples. Various types of connection state detection are conceivable depending on types of cables.

The second control unit 10 detects whether or not the second connector unit C2 is connected to the device 101. The second control unit 10 can detect whether or not the second connector unit C2 is connected to the device 101 using the same configuration as the first control unit 7.

The first control unit 7 and the second control unit 10 may always detect the connection states of the corresponding connector units, or may detect the connection states on the occasion of the operation detections in the operation detection units.

Signals and the like output from each part included in the first connector unit C1 and the second connector unit C2 will be described.

The first operation detection unit 5 outputs a detection signal to the first control unit 7 in response to the event that an operation has been detected. Similarly, the second operation detection unit 8 also outputs a detection signal to the second control unit 10 in response to the event that an operation has been detected.

In addition, the first control unit 7 may notify the second control unit 10 of the event that an operation has been detected. Also, the second control unit 10 may notify the first control unit 7 of the event that an operation has been detected. In this case, the detection signal output by the first operation detection unit 5 may be directly output to both the first control unit 7 and the second control unit 10. Similarly, the detection signal output by the second operation detection unit 8 may be directly output to both the first control unit 7 and the second control unit 10.

The first notification unit 6 and the second notification unit 9 perform a notification in accordance with the connection information input from the first control unit 7 and the second control unit 10 in response to the signals (connection information) indicating the connection states input from the first control unit 7 and the second control unit 10. The first notification unit 6 and the second notification unit 9 may give a notification of a connection state or a non-connection state.

Specifically, the first notification unit 6 gives a notification of whether or not the first connector unit C1 is connected (connection state) on the basis of the signal output from the first control unit 7 in response to the event that the second operation detection unit has detected an operation. In this case, the first control unit 7 may receive a notification from the second control unit 10 that the second operation detection unit 8 has detected an operation and give a notification of the connection state of the detected first connector unit C1, or may receive a notification from the second operation detection unit 8 that an operation has been detected without going through the second control unit 10 and give a notification of the connection state of the first connector unit C1.

Alternatively, the first notification unit 6 gives a notification of the connection state of the second connector unit C2 on the basis of the signal output from the first control unit 7 in response to the event that the first operation detection unit 5 has detected an operation. In this case, the first control unit 7 may receive information (connection information) about the connection state of the second connector unit C2 from the second control unit 10 and output a signal to the first notification unit 6 in accordance with the information, or may acquire information about the connection state of the second connector unit C2 without going through the second control unit 10 and output a signal to the first notification unit 6 in accordance with the information. Also, in this case, the second control unit 10 may transmit the connection information about the second connector unit C2 to the first control unit 7 by recognizing the event that the first operation detection unit 5 has detected the operation, or may transmit the connection information about the second connector unit C2 in accordance with a request from the first control unit 7 without recognizing the operation detection of the first operation detection unit 5.

Similarly, the second notification unit 9 may also give a notification of the connection state of the first connector unit C1 on the basis of the signal output from the second control unit 10 in response to the event that the first operation detection unit 5 has detected the operation, or may give a notification of the connection state of the first connector unit C1 on the basis of the signal output from the second control unit 10 in response to the event that the second operation detection unit 8 has detected the operation. In this case, the second control unit 10 may receive the connection information about the first connector unit C1 from the first control unit 7 and output a signal to the second notification unit 9 in accordance with the information, or may acquire the connection information about the first connector unit C1 without going through the first control unit 7 and output a signal to the second notification unit 9 in accordance with the information.

Further, the first control unit 7 and the second control unit 10 are preferably configured such that the detection information is synchronized for them to share information about the connection states (connection information) with each other. For example, in a case in which the first control unit 7 and the second control unit 10 are microcomputers, the first control unit 7 and the second control unit 10 are configured to be able to recognize the connection states between the first connector unit C1 and the device 100 and between the second connector unit C2 and the device 101 through mutual communication. Also, one microcomputer mounted on one connector unit may have functions of both the first control unit 7 and the second control unit 10.

Even when the first control unit 7 and the second control unit 10 are logic circuits or the like, it is desirable that each of them adopt a configuration in which its own connection information is transmitted to the other side.

The first control unit 7 receives, for example, a notification that the first operation detection unit 5 or the second operation detection unit 8 has detected an operation of the operator and gives the first notification unit 6 a notification instruction in accordance with the connection state of the first connector unit C1 or the second connector unit C2. The notification instruction is given by outputting a signal in accordance with a connection state of a connector unit serving as a notification target. For example, the first control unit 7 may detect a high potential (H) in a state in which the first connector unit C1 and the device 100 are connected to each other, detect a low potential (L) in a state in which they are not connected to each other, and output a signal in accordance with each of H/L to the first notification unit 6. As a result, a notification mode for the first connector unit C1 in the first notification unit 6 is realized. The second connector unit C2 can have the same configuration.

There are several possible combinations of the control units and the notification units. For example, the notification mode may be realized by the first control unit 7 outputting a signal in accordance with the connection state of the connector unit serving as the notification target to the first notification unit 6.

Alternatively, the first control unit 7 may output a signal in accordance with the connection state of the connector unit serving as the notification target to the second notification unit 9 via the second control unit 10.

Further, the first control unit 7 may directly output it to the second notification unit 9 without going through the second control unit 10.

A similar variation can be considered for a case in which the second control unit 10 outputs a signal to each notification unit.

Also, a configuration in which the notification instruction is given by not outputting a signal may be adopted. For example, a configuration in which the first control unit 7 stops a notification operation of the first notification unit 6 by not outputting a signal to the first notification unit 6 in a case in which the connector unit serving as the notification target is not connected, thereby notifying the operator that the connector unit serving as the notification target is not connected may be adopted.

In a state in which the first connector unit C1 is connected to the device 100, or a state in which the second connector unit C2 is connected to the device 101, it is conceivable to supply an operating voltage to the cable 1 from the device 100 or the device 101.

For example, the first connector unit C1 and the second connector unit C2 are respectively provided with power supply voltage terminals and ground terminals, and the cable unit 4 is provided with power line wiring and ground wiring (collectively described as a power supply voltage in FIG. 3) that provide connection between the power supply voltage terminals and between the ground terminals of the first connector unit C1 and the second connector unit C2.

In addition, the device 100 or the device 101 supplies an operation power supply voltage between the power supply voltage terminals and the ground terminals. This operation power supply voltage is an operation power supply voltage of the first operation detection unit 5, the first notification unit 6, and the first control unit 7 in the first connector unit C1 and is an operation power supply voltage of the second operation detection unit 8, the second notification unit 9, and the second control unit 10 in the second connector unit C2.

With such a configuration, operations in the cable 1 described below can be executed in a state in which at least one of the first connector unit C1 and the second connector unit C2 is connected to the device 100 or the device 101.

Also, even when the operation power supply voltage is not supplied from the device 100 or the device 101, a battery may be disposed in the cable 1 so that the cable 1 can execute the operations described later. In addition, even when the battery is disposed in the cable 1, the battery may be used to execute the operations described later in the case in which the operation power supply voltage is supplied from the device 100 or the device 101. As a result, it is possible to avoid a problem that the battery has been exhausted in a state in which the operation power supply voltage is not supplied so that operations cannot be executed when required.

In a case in which the cable 1 is provided with a battery, the first control unit 7 and the second control unit 10 may always detect the connection states of the corresponding connector units. In a case in which a battery is not provided, the connection states may be detected on the occasion of the operation detections in the operation detection units. As a result, it is possible to avoid a problem that the battery has been exhausted so that operations cannot be executed when required.

The first control unit 7 and the second control unit 10 may be configured by adopting, for example, microcomputers or the like, or may be configured by using logic circuits. Further, they may be configured as drive circuits for driving the first notification unit 6 and the second notification unit 9 in accordance with detection signals.

Although an example in which the first control unit 7 functions as a control unit that controls overall operations of the first connector unit C1 has been described in the block diagram shown in FIG. 3, other parts may have a function as a control unit, or a separate control unit may be provided. The same applies to the second connector unit C2.

Also, although an example in which the first connector unit C1 is provided with the first operation detection unit 5 and the first notification unit 6, and the second connector unit C2 is provided with the second operation detection unit 8 and the second notification unit 9 has been described, the cable may be the cable 1 provided with only one of the first operation detection unit 5 and the second operation detection unit 8, or the cable 1 provided with only one of the first notification unit 6 and the second notification unit 9.

### 2. Examples of Notification Mode

Examples of the notification modes of the first notification unit 6 and the second notification unit 9 will be described. Specifically, various notifications are made depending on whether or not the first connector unit C1 or the second connector unit C2 is connected to the device 100 or the device 101. Also, depending on the examples, not only information about whether or not a connector unit is connected but also other information is notified.

In addition, the cable 1 will be described assuming that any of the notification units performs a notification in a state in which the first connector unit C1 is connected to the device 100 or a state in which the second connector unit C2 is connected to the device 101. That is, in a state in which the first connector unit C1 and the second connector unit C2 are not connected to any of the devices, the operation voltage is not supplied to the notification units and the notification operation cannot be performed.

Although an example in which operation switches using mechanical switches are provided as the first operation detection unit 5 and the second operation detection unit 8 will be described, contact sensors or proximity sensors may be used.

Also, although an example in which notification light emitting units using light emitting elements are provided as the first notification unit 6 and the second notification unit 9 will be described, sound output units or vibration generation units may be used.

In addition, in each example, even if the same operation is performed while the first connector unit C1 has been exchanged with the second connector unit C2, the effects described in each notification mode can be obtained.

### <2-1. First Notification Mode>

A first notification mode is a notification mode in a case in which the second operation detection unit 8 detects an operation of the operator in a state in which the first connector unit C1 is connected to the device 100 and the second connector unit C2 is not connected to the device 101.

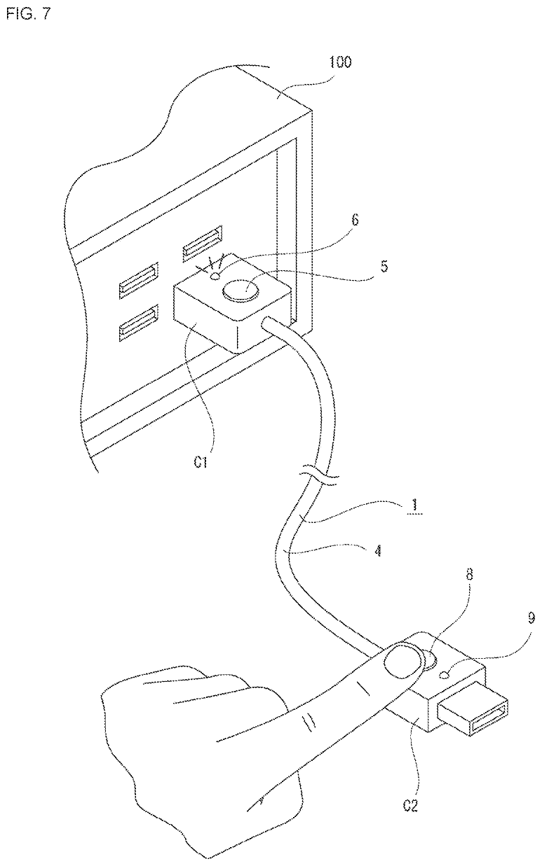

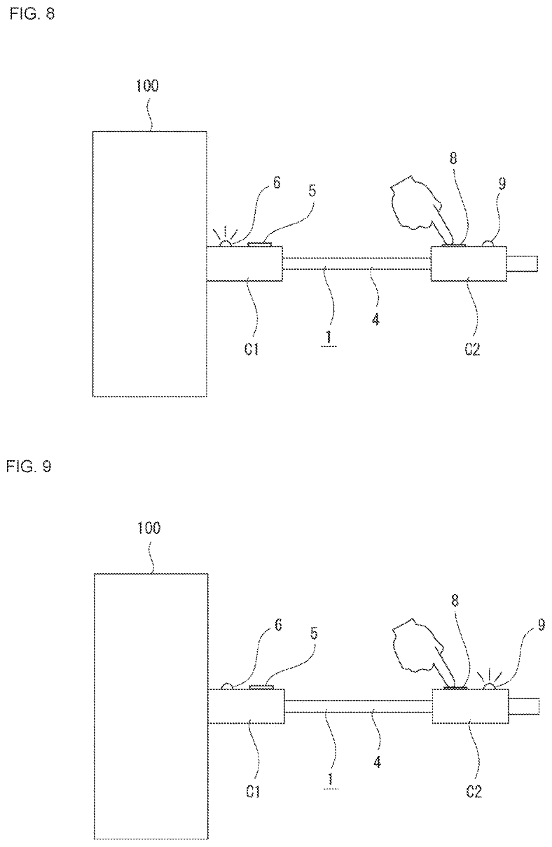

In the first notification mode, as shown in FIG. 7, the first notification unit 6 performs a light emitting operation, thereby giving a notification of a position of the first connector unit C1 paired with the second connector unit C2. As a result, in a case in which both of the second connector unit C2 and the first connector unit C1 are located within the sight of the eyes, the operator can identify the first connector unit C1 on a side opposite to the second connector unit C2. In particular, in a situation in which the cable unit 4 connecting the first connector unit C1 with the second connector unit C2 is bundled together with a large number of other cables, or other situations, it may be difficult to confirm a paired connector unit. Under such circumstances, a notification according to the first notification mode is effective. Also, FIG. 8 is a diagram schematically showing the state shown in FIG. 7. In the following description, schematic diagrams will be used as appropriate.

In addition, by emitting light from the first notification unit 6 of the first connector unit C1, it is also possible to give a notification that the first connector unit C1 is in a state in which it has been connected to the device 100. In other words, in a case in which the first connector unit C1 is not connected to the device 100 and is in a free state, that is, neither of the first connector unit C1 nor the second connector unit C2 is connected to the devices and is in a free state, operation power is not supplied and the first notification unit 6 cannot perform the light emitting operation. Due to the first notification unit 6 not emitting light, it is possible to make the operator recognize the state in which the first connector unit C1 is not connected.

In order to realize the first notification mode, the first notification unit 6 needs to recognize that the second operation detection unit 8 of the second connector unit C2 has been operated. For that purpose, the operation of the second operation detection unit 8 is notified to the first notification unit 6 of the first connector unit C1 via the transmission line 11.

The notification may be executed by a control unit included in the second connector unit C2, or the notification may be considered as having been performed when the first notification unit 6 detects, via the transmission line 11, an analog value (a voltage value or the like) that changes as the second operation detection unit 8 of the second connector unit C2 has been pressed.

In a case in which the first notification unit 6 directly detects an operation on the second operation detection unit 8, the notification mode may be expressed in response to the change in the analog value. Further, in a case in which the first notification unit 6 directly detects an operation on the second operation detection unit 8 to perform a notification, it is necessary that the first notification unit 6 has acquired the connection information about the first connector unit C1. With respect to this, for example, by constantly receiving a signal output based on the connection information about the first connector unit C1 from the first control unit 7, the first notification unit 6 can realize the notification mode on the basis of the output signal and the operation detection of the second operation detection unit 8. Such a configuration can be realized by a digital circuit, a logic circuit, or the like, and it is also possible to eliminate the need for control of each part using a program or the like.

For example, the notification of the first notification unit 6 may be performed by transmitting the detection signal of the second operation detection unit 8 to the first notification unit 6 of the first connector unit C1.

Also, the detection signal of the second operation detection unit 8 may be transmitted to the first notification unit 6 via the first control unit 7 of the first connector unit C1.

Further, the detection signal of the second operation detection unit 8 may be transmitted to the first notification unit 6 via the second control unit 10 and the first control unit 7.

Also, the detection signal of the second operation detection unit 8 may be transmitted to the first notification unit 6 via the second control unit 10. Furthermore, the notification operation performed by the first notification unit 6 may be realized by transmitting the detection signal of the second operation detection unit 8 to the first control unit 7 of the first connector unit C1 and transmitting a control signal from the first control unit 7 to the first notification unit 6.

Moreover, the notification operation may be realized by transmitting the detection signal of the second operation detection 8 to the second control unit 10 and transmitting a control signal from the second control unit 10 directly to the first notification unit 6 or transmitting it via the first control unit 7 to the first notification unit 6.

These notifications are the same in each example described later.

### <2-2. Second Notification Mode>

A second notification mode is a notification mode in a case in which the second operation detection unit 8 detects the operation of the operator in a state in which the first connector unit C1 is connected to the device 100 and the second connector unit C2 is not connected to the device 101. That is, the connection state of each connector unit is the same as that in the first notification mode.

In the second notification mode, as shown in FIG. 9, the second notification unit 9 performs a light emitting operation in response to the operation of the operator, and the connection state of the first connector unit C1 is notified.

The second notification mode is an effective notification mode, for example, in a state in which the operator can visually recognize the nearby present second connector unit C2 and cannot visually recognize the first connector unit C1 connected to the device 100 located in the next room or the like, or in other states.

Specifically, the second notification unit 9 performs a notification in response to the event that the second operation detection unit 8 has detected the operation of the operator. In the state in which the first connector unit C1 is connected to the device 100, the second notification unit 9 performs a light emitting operation to thereby perform the notification that the first connector unit C1 has been connected to the device.

On the other hand, in the state in which the first connector unit C1 is not connected to the device 100, the second notification unit 9 does not perform the light emitting operation even though the second operation detection unit 8 has been operated, whereby the operator can be notified of the event that the first connector unit C1 is not connected to the device 100.

Also, the first notification mode and the second notification mode may be carried out at the same time. Specifically, in a case in which the second operation detection unit 8 of the second connector unit C2 has detected the operation of the operator, both of the first notification unit 6 and the second notification unit 9 perform a light emitting operation in a state in which the first connector unit C1 has been connected to the device 100.

Further, in a case in which the second operation detection unit 8 has detected the operation of the operator, neither the first notification unit 6 nor the second notification unit 9 performs (or can perform) a light emitting operation in a state in which the first connector unit C1 is not connected to the device 100, As a result, a reliable notification can be performed regardless of whether the first connector unit C1 is visible to the operator or not.

In addition, the second notification mode is preferable to the first notification mode for a case in which a vibration generation unit is used as the second notification unit 9 That is, it is possible to perform a more reliable notification by vibrating the second connector unit C2, which is an operation target of the operator, than by vibrating the first connector unit C1 which is not an operation target.

### <2-3. Third Notification Mode>

A third notification mode is a notification mode in a case in which the first operation detection unit 5 has detected the operation of the operator in a state in which the first connector unit C1 is connected to the device 100 and the second connector unit C2 is not connected to the device 101.

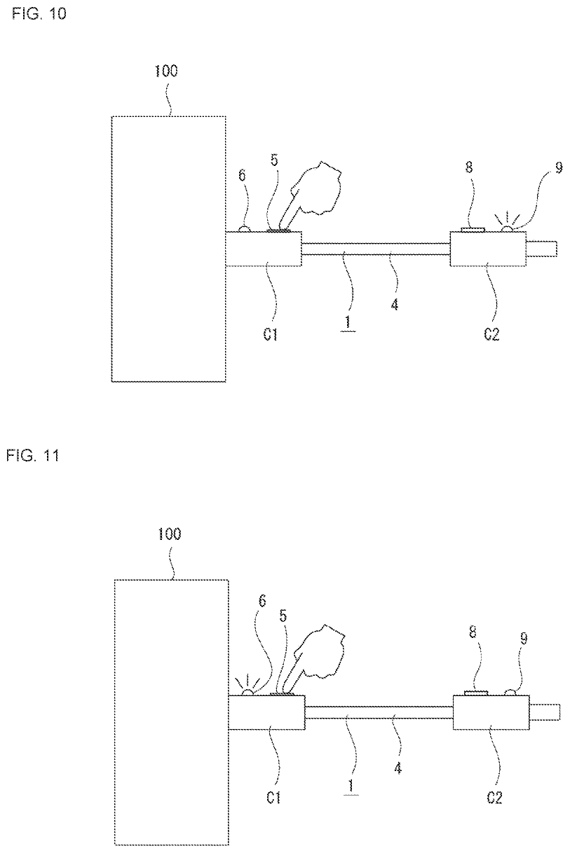

In the third notification mode, as shown in FIG. 10, the second notification unit 9 performs a light emitting operation in response to the operation detection of the first operation detection unit 5, and a position of the second connector unit C2 is notified. Also, the event that the second connector unit C2 is not connected to the device 101 may be notified using a light emitting pattern or the like.

The third notification mode is suitable, for example, for a case in which a plurality of cables are bundled and two paired connector units cannot be identified. That is, the operator who wants to ascertain the state of the connector unit on the other end side operates one of the connector units present nearby (first connector unit C1), thereby confirming a light emitting operation performed by the second notification unit 9 of the connector unit on the other end side (second connector unit C2) and specifying the connector unit on the other end side.

Also, the notification that the second connector unit C2 is not connected to the device 101 is performed using the light emitting pattern, which is useful in a case in which it is difficult to visually recognize whether or not the second connector unit C2 has been connected.

### <2-4. Fourth Notification Mode>

Similarly to the third notification mode, a fourth notification mode is a notification mode in a case in which the first operation detection unit 5 has detected the operation of the operator in a state in which the first connector unit C1 is connected to the device 100 and the second connector unit C2 is not connected to the device 101.

In the fourth notification mode, as shown in FIG. 11, the first notification unit 6 performs a light emitting operation in response to the operation detection of the first operation detection unit 5, thereby notifying the operator of a position and a connection state of the second connector unit C2.

The fourth notification mode is suitable for the operator to ascertain a connection state of the invisible second connector unit C2, for example, in a case in which the second connector unit C2 is present at a position at which it cannot be visually recognized, or other cases.

Although both of the third notification mode and the fourth notification mode are notification modes that notify the operator of the connection state of the second connector unit C2, which is on the other end side of the first connector unit C1 in which the operation has been detected, the fourth notification mode is preferably used in a case in which a vibration generation unit is used as the first notification unit 6 or the second notification unit 9. That is, since it is conceivable that the first connector unit C1 which the operator sets as the operation target is located within the reach of the operator, it is suitable to vibrate the first connector unit C1 for giving a notification to the operator.

### <2-5. Fifth Notification Mode>

A fifth notification mode is a notification mode in a case in which the first operation detection unit 5 has detected the operation of the operator in a state in which the first connector unit C1 is connected to the device 100 and the second connector unit C2 is connected to the device 101.

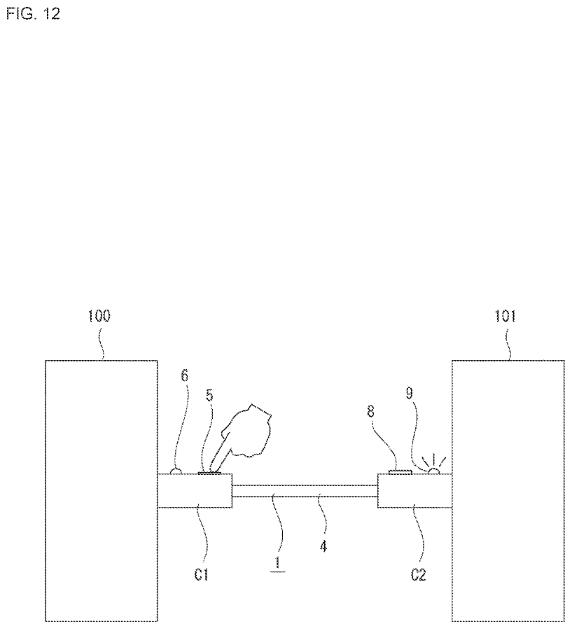

In the fifth notification mode, as shown in FIG. 12, the second notification unit 9 performs a light emitting operation in response to the operation detection of the first operation detection unit 5, thereby notifying the operator of the position and connection state of the second connector unit C2.

The fifth notification mode is suitable for a situation in which, for example, the cable unit 4 is bundled with another cable so that the second connector unit C2 paired with the first connector unit C1 cannot be confirmed.

Also, in the fifth notification mode, the first connector unit C1 and the second connector unit C2 are connected to the device 100 and the device 101, respectively. In this situation, not only the notification of the second connector unit C2 being connected to the device 101, but also the notification of other information may be included.

For example, in a case in which the cable 1 is a communication cable for performing information communication between the device 100 and the device 101, by using the second notification unit 9 to express a lighting pattern in accordance with a communication speed between the device 100 and the device 101 performed via the cable 1, more information can be transmitted to the operator.

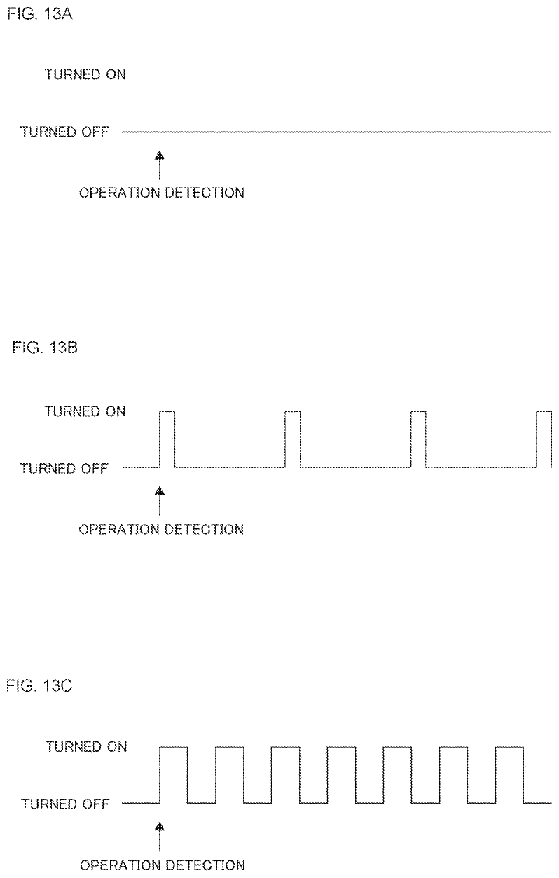

Specifically, this will be described with reference to FIG. 13.

In a case in which the first operation detection unit 5 has detected the operation of the operator in a state in which the first connector unit C1 is connected to the device 100, when the second connector unit C2 is not connected to the device 101 (that is, the third notification mode described above), the notification light emitting unit serving as the second notification unit 9 is turned off even after the operation is detected as shown in FIG. 13A, whereby the connection state of the second connector unit C2 (that is, the fact that the second connector unit C2 is not connected) is notified.

Further, in a case in which the second connector unit C2 is connected to the device 101 and the communication speed between the device 100 and the device 101 performed via the cable 1 is less than a predetermined speed, the notification to the operator is performed in a light emitting mode in which light is blinked with a longer light emitting cycle as shown in FIG. 13B.

On the other hand, in a case in which the second connector unit is connected to the device 101 and the communication speed performed via the cable 1 is equal to or higher than the predetermined speed, the notification to the operator is performed in a light emitting mode in which light is blinked with a shorter light emitting cycle as shown in FIG. 13C.

Information about the communication speed is transmitted from the device 100 or the device 101 to the first connector unit C1 or the second connector unit C2. Alternatively, at least one of the first connector unit C1 and the second connector unit C2 may be provided with a measurement unit for measuring the communication speed.

In any case, it can be realized by providing a communication speed detection unit capable of acquiring communication speed information in one of the connector units.

Also, as shown in FIGS. 13B and 13C, which of the two lighting patterns (blinking patterns) is expressed may be determined in accordance with two patterns depending on whether or not the speed is equal to or higher than the predetermined speed, or 10 types of lighting patterns may be determined in accordance with the communication speed subdivided into 10 stages and the like. Further, by determining a lighting interval to be proportional (or inversely proportional) to the communication speed, a substantially stepless notification mode may be used.

Also, the emission color may be changed in accordance with the communication speed. For example, in a case in which the speed is lower than the predetermined speed, the notification may be performed by lightening the second notification unit 9 in red, and in a case in which the speed is higher than the predetermined speed, the notification may be performed by lighting the second notification unit 9 in green. Further, a lighting color may be changed steplessly in accordance with the communication speed. According to this mode, since a minute change in communication speed can be ascertained due to the lighting color, it is possible to contribute to finding a problem or the like.

Even in the case of changing the lighting pattern or changing the lighting color, the operator can ascertain the communication speed between devices simply by operating the first connector unit C1, and thus it is possible to easily find a case in which there is a problem that the communication speed is unintentionally lowered, thereby achieving an improvement in convenience.

Further, in the case of performing not only the operation on the first connector unit C1 but also the operation on the second connector unit C2, the second operation detection unit 8 performs the detection and the second notification unit 9 performs the notification based on the communication speed, whereby the communication speed can be ascertained by operating the connector unit that is easier to operate out of the two connector units provided at both ends of the cable unit 4, and thus it can contribute to the improvement in convenience and early finding of problems.

As yet another example, the lighting pattern may be changed on the basis of a relationship between performance of the cable 1 and the communication speed. Specifically, USB2.0 and USB3.0, which are USB standards, will be described as an example.

USB2.0 is a standard with a theoretical maximum data transfer rate of 480 Mbps. In addition, USB3.0 is a standard in which the theoretical maximum data transfer rate is 5 Gbps.

In order to take out the transfer performance (communication speed performance) of USB3.0, the cable 1 as a USB cable needs to support the USB3.0 standard, and a USB port of the device 100 to which the cable 1 is connected also needs to support the USB3.0 standard. That is, in a case in which neither the cable 1 nor the USB port of the device 100 supports the USB3.0 standard, the transfer performance of USB3.0 cannot be taken out.

In a case in which the cable 1 supports the USB2.0 standard, the second notification unit 9 has a lighting pattern with a longer lighting interval as shown in FIG. 13B even when the USB port of the device 100 or the device 101 supports USB3.0. This notifies the operator that only low-speed communication based on the USB2.0 standard is possible.

Further, in a case in which either the USB port of the device 100 or the device 101 does not support USB3.0 even if the cable 1 supports the USB3.0 standard, the second notification unit 9 adopts the lighting pattern shown in FIG. 13B.

On the other hand, in a case in which the cable 1 supports the USB3.0 standard and the USB port of the device 100 or device 101 supports USB3.0, the second notification unit 9 adopts a lighting pattern with a shorter lighting interval as shown in FIG. 13C. This notifies the operator that high-speed communication based on the USB3.0 standard is possible.

Information about whether or not each USB port of the device 100 or the device 101 supports the USB3.0 standard may be obtained from the device 100 or the device 101, or the lighting pattern may be configured to be changed in accordance with the communication speed measured by the measurement unit provided in each connector unit.

Further, the lighting pattern shown in FIGS. 13B and 13C may be configured to be expressed only in a case in which communication is actually performed between the device 100 and the device 101, or the lighting pattern shown in FIGS. 13B and 13C may be configured to be expressed in a case in which communication is not actually performed.

As an example of the latter, for example, the first connector unit C1 may acquire standard information about the USB port from the device 100 when the first connector unit C1 of the cable 1 is connected to the USB port of the device 100, the second connector unit C2 may acquire standard information about the USB port from the device 101 when the second connector unit C2 is connected to the USB port of the device 101, and the lighting pattern shown in FIG. 13B and the lighting pattern shown in FIG. 13C may be expressed by the second notification unit 9 for a predetermined number of seconds after both ends of the cable 1 are connected to the USB port.

As a result, when both connector units are connected to the devices, the operator can receive a notification as to whether or not a communication path capable of high-speed communication has been established, and thus it is possible to make an on-the-spot judgment as to whether or not the intended connection can be made.

As another example of giving a notification of information other than the connection state of the second connector unit C2 using a lighting mode of the second notification unit 9, a case in which the device 101 is a charging device and the device 100 is a charging target device such as a mobile phone will be described.

In such a situation, it is conceivable to perform a notification in accordance with a charge amount (a value obtained by dividing a current charge amount by the maximum charge amount multiplied by 100).

For example, the device 100 notifies the first connector unit C1 of information about the charge amount. That is, the first connector unit C1 is provided with a charge state detection unit capable of acquiring a charge state of the device 100.

The first notification unit 6 of the first connector unit C1 causes the notification mode to be expressed in accordance with a level of the charge amount on condition that a notification that the second connector unit C2 has detected the operation has been given and that the charge state detection unit has detected the charge state. Specifically, in a case in which the charge amount of the device 100 is less than a predetermined value (for example, 80%), a light emitting operation is performed in accordance with the lighting pattern with the lighting interval as shown in FIG. 13B. Further, in a case in which the charge amount of the device 100 is equal to or more than a predetermined value, a light emitting operation is performed in accordance with a lighting pattern with a lighting interval as shown in FIG. 13C. As a result, the operator can ascertain the charge amount of the device 100 without operating the device 100, which is highly convenient.

Also, in this example, the notification mode has two stages (a case of less than a predetermined value or a case of a predetermined value or more), but the notification mode may be changed to have more detailed stages. For example, by changing the notification mode (lighting interval) in increments of 10%, the operator can ascertain the charge amount more accurately.

Further, in addition to changing the lighting interval, the charge amount may be notified by changing the lighting color. Of course, the notification light emitting unit provided in the first connector unit C1 may give a notification of the connection state of the first connector unit C1, and the sound output unit provided in the first connector unit C1 may give a notification of the charge amount.

When the fifth notification mode is applied to the case in which many charging target devices 100 are connected to the device 101 serving as the charging device, the second connector unit C2 on the device 101 side performs the operation detection, and the first connector unit C1 performs a light emitting operation, so that a notification is performed in accordance with the connection state and the charge amount. That is, it is possible for the operator to ascertain which of the many connected charging target devices 100 is charged to what extent, and thus when the charging of the device 100 has been completed, the work efficiency at the time of removing the second connector unit C2 from the device 101 can be improved. Further, since the device 100 corresponding to the second connector unit C2 that is to be removed due to the completion of charging can be easily identified, it is possible to prevent the connector unit connected to another device from being accidentally removed.

Also, in a case in which the device 100 is a charging device and the device 101 is a charging target device, the notification operation of the first notification unit 6 of the first connector unit C1 connected to the charging device is performed by operating the second connector unit C2 connected to the charging target device. As a result, by operating the second connector unit C2 connected to its own mobile phone or the like, a port on the device 100 side to which the mobile phone is connected is specified, and thus it is possible to reduce the possibility that the connector unit is unintentionally removed. That is, the convenience is improved.

### <2-6. Sixth Notification Mode>

Similarly to the fifth notification mode, a sixth notification mode is a notification mode in a case in which the first operation detection unit 5 has detected the operation of the operator in a state in which the first connector unit C1 is connected to the device 100 and the second connector unit C2 is connected to the device 101.

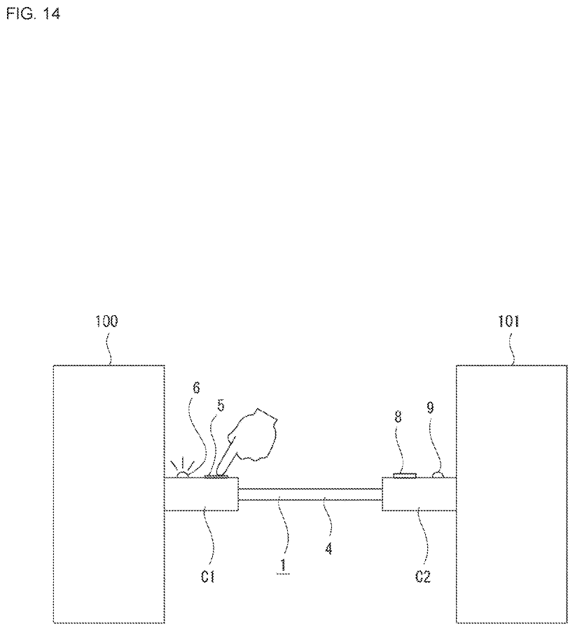

In the sixth notification mode, as shown in FIG. 14, the connection state of the second connector unit is notified to the operator by performing the light emitting operation using the first notification unit 6 in response to the operation detection of the first operation detection unit 5. The sixth notification mode is suitable for the operator to ascertain the connection state of the invisible second connector unit C2, for example, in a case in which the second connector unit C2 is present at a position at which it cannot be visually recognized, or in other cases.

Further, as described in the fifth notification mode, by performing not only the notification as to whether or not the second connector unit C2 is connected to the device 101, but also the notification in accordance with the communication speed and the charge amount of the device, information may be provided to the operator.

According to the sixth notification mode, since the first notification unit 6 of the first connector unit C1 serving as the operation target performs the notification operation, the information about the charge amount and the connection state of the device 101 can be ascertained even when the position or the like of the device 101 on the other side is not known. As a result, an improvement in work efficiency can be achieved.

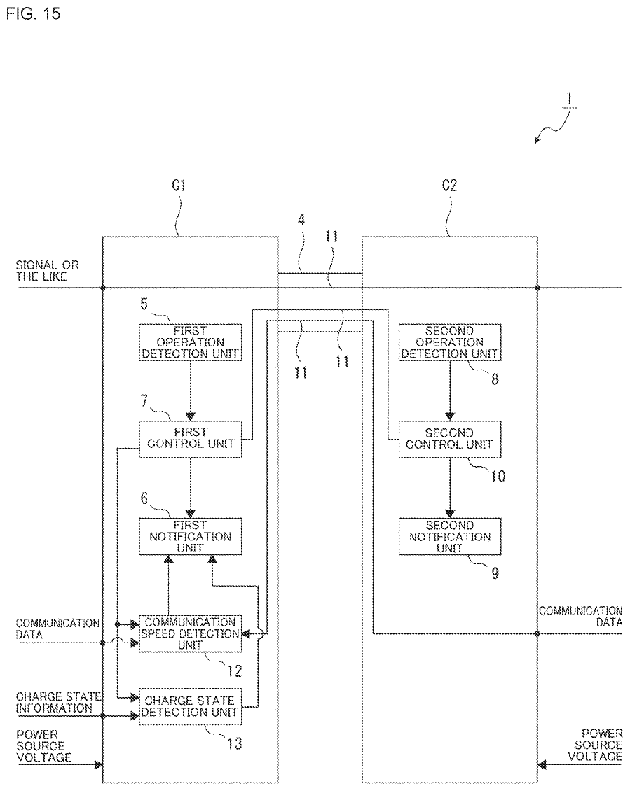

FIG. 15 shows a block diagram of the first connector unit C1 and the second connector unit C2 for realizing the fifth notification mode and the sixth notification mode.

The first connector unit C1 includes a communication speed detection unit 12 and a charge state detection unit 13 in addition to the first operation detection unit 5, the first notification unit 6, and the first control unit 7.

The second connector unit C2 includes the second operation detection unit 8, the second notification unit 9, and the second control unit 10.

The charge state detection unit 13 may be provided in both the first connector unit C1 and the second connector unit C2.

Also, the communication speed detection unit 12 and the charge state detection unit 13 may be provided in the second connector unit C2. Further, either the communication speed detection unit 12 or the charge state detection unit 13 may not be provided. For example, in a case in which the first notification unit 6 and the second notification unit 9 perform a notification in accordance with the connection state and the communication speed, the charge state detection unit 13 may not be provided. Also, in a case in which the first notification unit 6 and the second notification unit 9 perform a notification in accordance with the charge state of the charging target device, the communication speed detection unit 12 may not be provided.

Communication data between devices is input to the communication speed detection unit 12. By detecting the communication data, it is possible to detect the communication speed in information communication between devices. Information about the communication speed may be obtained from each device.

The charge state detection unit 13 can acquire information about the charge state from the charging target device.

Also, in the state shown in FIG. 15, the device 100 to which the first connector unit C1 is connected is the charging target device (a mobile phone or the like), and the device 101 to which the second connector unit C2 is connected is the charging device.

### 3. Flowchart in First to Sixth Notification Modes

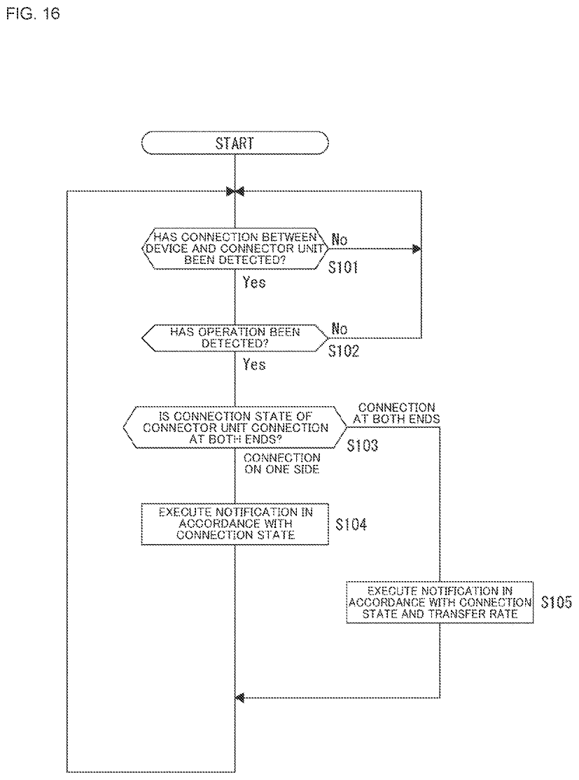

A flowchart for carrying out the first to sixth notification modes will be described with reference to FIG. 16.

First, the connector unit (first connector unit C1 or second connector unit C2) determines in step S101 whether or not the connection between the device and the connector unit has been detected. In this determination process, for example, in a case in which the event that either the first connector unit C1 or the second connector unit C2 has been connected to the device 100 or the device 101 is detected, the process determines “Yes” to proceed. That is, in a case in which the flowchart shown in FIG. 16 is executed independently by the first connector unit C1 and the second connector unit C2, any of the connector units determines “Yes” in the determination process of step S101 in a case in which the event that any one of the connector units has been connected to the device is detected.

The connector unit determines in step S102 whether or not an operation performed by the operator has been detected. This process is, for example, a branch process depending on whether or not the operation on itself (connector unit) has been detected. That is, in a case in which the operator has performed the operation on the first connector unit C1, the first connector unit C1 determines “Yes” in the process of step S102, but the second connector unit C2 determines “No” in the process of step S102.

In a case in which the determination process in either step S101 or step S102 determines “No”, the process returns to step S101 again.

Also, in a case in which any of the processes of step S101 and step S102 determines “Yes”, the process proceeds to the subsequent process of step S103.

In step S103, the connector unit performs a branch process in accordance with the connection states of the first connector unit C1 and the second connector unit C2 at both ends of the cable 1. Also, the first connector unit C1 can acquire not only the connection state of the first connector unit C1 but also the information about the connection state (connection information) of the second connector unit C2.

In a case in which it is determined that only one of the first connector unit C1 and the second connector unit C2 is connected (in other words, only one is not connected) in step S103, the connector unit executes a notification in accordance with the connection state in step S104.

For example, according to the first notification mode described above, the second connector unit C2 executes the process of step S104 in response to the event that the second operation detection unit 8 of the second connector unit C2 has detected the operation. At that time, the notification of the first notification unit 6 of the first connector unit C1 is executed. In this process, for example, the second control unit 10 of the second connector unit C2 transmits a control signal (detection signal) based on the operation detection of the second operation detection unit 8 to the first notification of the first connector unit C1 via the transmission line 11 of the cable unit 4, thereby causing the notification operation to be executed.

Further, according to the second notification mode described above, the second notification unit 9 executes the process of step S104 in response to the event that the second operation detection unit 8 of the second connector unit C2 has detected the operation. In this case, the process from the operation detection to the notification is completed inside the second connector unit C2.

According to the third notification mode described above, the first connector unit C1 executes the process of step S104 in response to the event that the first operation detection unit 5 of the first connector unit C1 has detected the operation. At that time, the notification of the second notification unit 9 of the second connector unit C2 is executed. In this process, for example, the first control unit 7 of the first connector unit C1 transmits a control signal (detection signal) based on the operation detection of the first operation detection unit 5 to the second notification unit 9 of the second connector unit C2 via the transmission line 11 of the cable unit 4, thereby causing the notification operation to be executed. In other words, the second notification unit 9 detects that the first operation detection unit 5 of the first connector unit C1 has detected the operation and performs the notification operation.

According to the fourth notification mode described above, the first notification unit 6 executes the process of step S104 in response to the event that the first operation detection unit 5 of the first connector unit C1 has detected the operation. In this case, the process from the operation detection to the notification is completed inside the first connector unit C1.

In a case in which both of the first connector unit C1 and the second connector unit C2 are determined to be in a connected state in step S103, the connector unit executes a notification in accordance with the connection states and the transfer rate in step S105.

For example, according to the fifth notification mode described above, the first connector unit C1 executes the process of step S105 in response to the event that the first operation detection unit 5 of the first connector unit C1 has detected the operation.

Specifically, the process is realized by the first control unit 7 of the first connector unit C1 transmitting a control signal based on the operation detection of the first operation detection unit 5 to the second notification unit 9 of the second connector unit C2 via the transmission line 11 of the cable unit 4.

Also, according to the sixth notification mode described above, the first connector unit C1 executes the notification operation of the first notification unit 6 as the process of step S105 in response to the event that the first operation detection unit 5 of the first connector unit C1 has detected the operation. In this case, the process from the operation detection to the notification is completed inside the first connector unit C1.

Also, although an example of executing the notification in accordance with the connection states and the transfer rate has been described in the process of step S105 of FIG. 16, a configuration in which a notification is given in accordance with the connection states and the charge amount as described above may be adopted. Further, a configuration in which, in a state in which both of the connector units have been connected, only the notification in accordance with the connection states is executed without performing the notification in accordance with the transfer rate and the charge amount may be adopted. For example, in a state in which the first connector unit C1 is connected to the device 100, a notification mode for giving a notification of the state in which only one connector unit is connected to the device may be expressed in the process of step S104 in a case in which the second connector unit C2 is not connected to the device 101, and a notification mode for giving a notification of the state in which both of the connector units are all connected to the devices may be expressed in the process of step S105 in a case in which the second connector unit C2 is connected to the device 101. As a result, the operator can be notified of whether or not both of the connector units are in a connected state, and thus an improvement in work efficiency can be expected. Further, in this case, since a configuration for giving a notification of the transfer rate and the charge amount is not required, the configuration of each connector unit can be simplified, which can contribute to reduction of manufacturing processes and costs.

Also, the connection detection determination process in step S101 may be performed after the process in step S102. Specifically, after detecting the operation on the connector unit, the connection detection determination process may be performed. For example, in a case in which the cable 1 is provided with a battery, the cable 1 can execute a series of processes shown in FIG. 16 even when both ends are not connected, and thus a configuration in which the connection information of each connector unit is acquired on the occasion that the operation on the connector unit has been detected, and the notification in accordance therewith is performed may be adopted. Further, in that case, the branch process in the case in which both ends are not connected may be performed in addition to the determination process in step S103, and in a case in which both ends are not connected, the process may be performed such that a notification mode for giving a notification of the fact is expressed.

The same applies to other flowcharts described later.

### 4. Second Embodiment

A second embodiment different from the first embodiment described so far will be described with reference to the accompanying drawings.

The cable 1 of the second embodiment is characterized in that, in a state in which one connector unit (second connector unit C2 in the present example) is connected to a device (the device 101 in the present example), and the other connector unit (the first connector unit C1 in the present example) is not connected to a device, a notification unit performs a notification for guiding the other connector unit to a place to be connected in the device in a case in which an operation detection unit of the other connector unit has detected an operation.

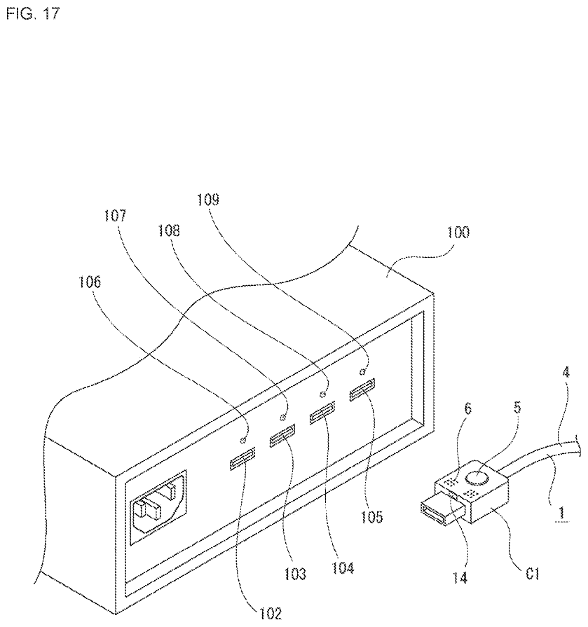

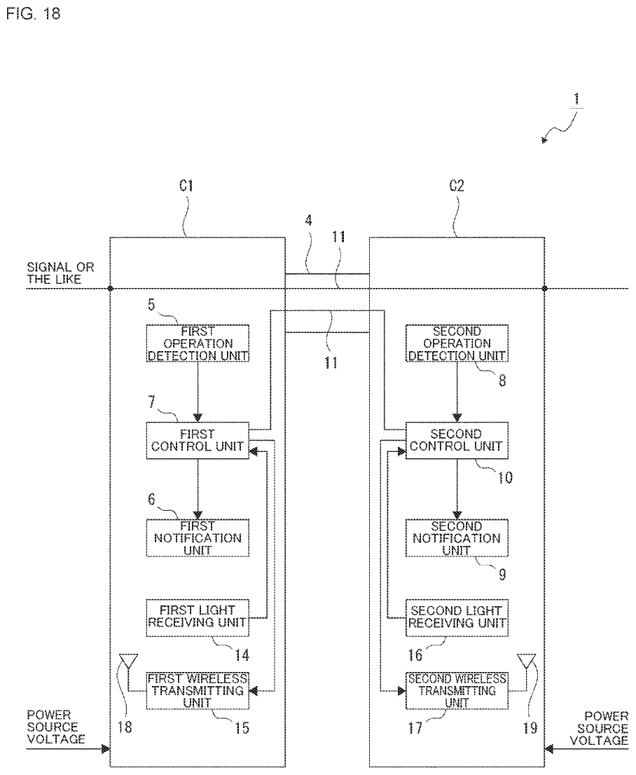

FIG. 17 shows an example of a usage mode of the cable 1 according to the second embodiment. Also, FIG. 18 shows an example of a block diagram of the cable 1 according to the second embodiment.

The first connector unit C1 of the cable 1 is provided with the first operation detection unit 5 that employs a mechanical switch and the first notification unit 6 serving as a sound output unit.

Further, the first connector unit C1 is provided with a first light receiving unit 14 that receives light and a first wireless transmitting unit 15 that performs wireless trigger transmission to a device.

Similarly, the second connector unit C2 is provided with the second operation detection unit 8 that employs a mechanical switch, the second notification unit 9 serving as a sound output unit, a second light receiving unit 16, and a second wireless transmitting unit 17.

The first connector unit C1 is provided with a first antenna 18 with which the first wireless transmitting unit 15 transmits information (see FIG. 18). Similarly, the second connector unit C2 is provided with a second antenna 19 with which the second wireless transmitting unit 17 transmits information (see FIG. 18).

In the present example, since the notification for guiding the first connector unit C1 to a predetermined place is performed, the first connector unit C1 will be taken as an example to describe a mechanism of guidance, but the same configuration is used in the case of performing a notification for guiding the second connector unit C2 to a predetermined place.

The first notification unit 6 outputs sound for guiding the first connector unit C1 to a predetermined place in response to a wavelength of light received by the first light receiving unit 14. Also, for that purpose, the first light receiving unit 14 may be configured to be able to receive only light having a specific wavelength.

For example, the first control unit 7 receives a notification that the first light receiving unit 14 has received light having a specific wavelength and gives a notification instruction to the first notification unit 6.

Also, although an example in which the first control unit 7 functions as a control unit that controls overall operations of the first connector unit C1 is shown in the block diagram shown in FIG. 18, another part may have a function as a control unit, or a separate control unit may be provided.

The first wireless transmitting unit 15 transmits a trigger for instructing the device 100 to emit light in response to the event that the first operation detection unit 5 has detected the operation of the operator (that is, in response to the event that the operator has pressed the mechanical switch serving as the first operation detection unit 5).

For example, the first control unit 7 receives detection results of the first operation detection unit 5 and instructs the first wireless transmitting unit 15 to transmit the trigger.

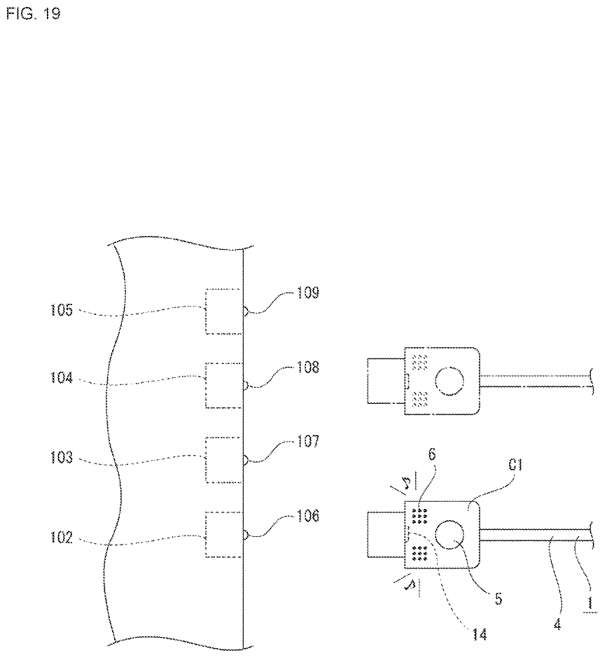

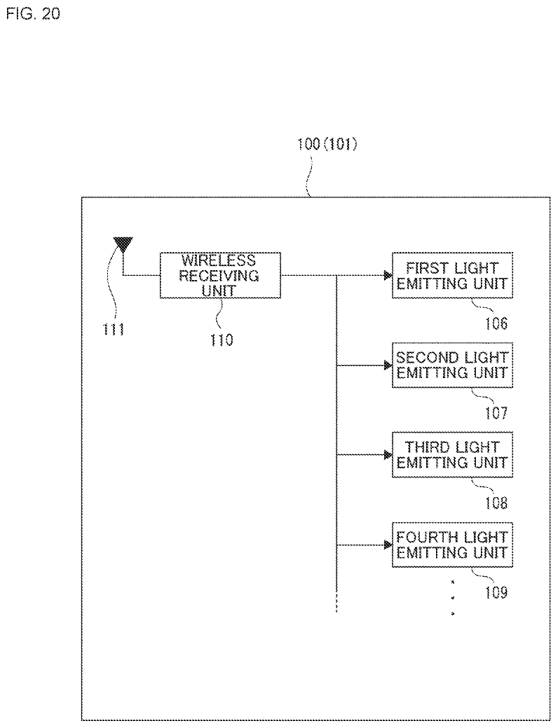

The device 100 to which the first connector unit C1 is connected will be described with reference to FIGS. 17 and 19. Also, FIG. 20 shows a block diagram of the device 100.

The device 100 is provided with a first connection part 102, a second connection part 103, a third connection part 104, and a fourth connection part 105 to which the connector unit is connected. In addition, a light emitting unit configured of a light emitting diode (LED) or the like is provided above each connection part. Specifically, a first light emitting unit 106 is provided above the first connection part 102, a second light emitting unit 107 is provided above the second connection part 103, a third light emitting unit 108 is provided above the third connection part 104, and a fourth light emitting unit 109 is provided above the fourth connection part 105

A wavelength of light emitted from the first light emitting unit 106 (a first wavelength), a wavelength of light emitted from the second light emitting unit 107 (a second wavelength), a wavelength of light emitted from the third light emitting unit 108 (a third wavelength), and a wavelength of light emitted from the fourth light emitting unit 109 (a fourth wavelength) are different from each other. For example, the first wavelength is a wavelength that becomes red light (for example, 700 nm), the second wavelength is a wavelength that becomes blue light (for example, 470 nm), the third wavelength is a wavelength that becomes green light (for example, 530 nm), and the fourth wavelength is a wavelength that becomes yellow light (for example, 580 nm).

Further, the device 100 is provided with a wireless receiving unit 110 that receives the trigger from the first wireless transmitting unit 15. Also, the device 100 is provided with an antenna 111 for the wireless receiving unit 110 to receive information (see FIG. 20).

The device 100 performs light emitting operations of the first light emitting unit 106, the second light emitting unit 107, the third light emitting unit 108, and the fourth light emitting unit 109 in response to receiving the trigger from the first wireless transmitting unit 15. Details of the light emitting operation will be described later.

By performing the light emitting operation in response to the reception of the trigger, it is possible to emit light at an appropriate timing and it is not necessary to always emit light, which can contribute to reduction of power consumption.

Also, the light emitting control of each light emitting unit may be performed by the control unit provided on the device 100 side. For example, the control unit of the device 100 may receive a reception signal from the wireless receiving unit 110, and a light emitting instruction may be given to an appropriate light emitting unit in accordance with the reception signal.

Also, as shown in FIG. 20, a light emitting unit may be provided in addition to the first light emitting unit 106, the second light emitting unit 107, the third light emitting unit 108, and the fourth light emitting unit 109. In that case, a connection part may be provided in addition to the first connection part 102, the second connection part 103, the third connection part 104, and the fourth connection part 105.

### <4-1. Seventh Notification Mode>

A seventh notification mode is a notification mode in a case in which the first operation detection unit 5 has detected the operation of the operator in a state in which the second connector unit C2 is connected to the device 101 and the first connector unit C1 is not connected to any device.

In the seventh notification mode, as shown in FIG. 19, an operation of the first notification unit 6 notifies the operator of a correct connection position. Specifically, in a case in which the operator moves the first connector unit C1 from a position substantially opposite to the first connection part 102 provided in the device 100 to a position substantially opposite to the fourth connection part 105, a notification sound is output at a specific position.

For example, in a case in which a correct connection destination of the cable 1 in the present example is the first connection part 102, the notification operation of the first notification unit 6 is performed when the first connector unit C1 has been located at a position substantially opposite to the first connection part 102.

As a result, in a case in which the connection work of the first connector unit C1 is to be performed at a position and posture at which a surface of the device 100 on which the connection part is provided cannot be visually recognized, it is possible to connect the first connector unit C1 to the first connection part 102 of the device 100 by groping with the help of the notification sound, thereby achieving an improvement in work efficiency.

Further, even in a case in which the operator can visually recognize the surface of the device 100 on which the connection part is provided, the notification based on the correct connection destination and an optimum connection destination is performed, and thus it is possible to inhibit occurrence of work mistakes and achieve the improvement in work efficiency.

### <4-2. Flowchart in Seventh Notification Mode>

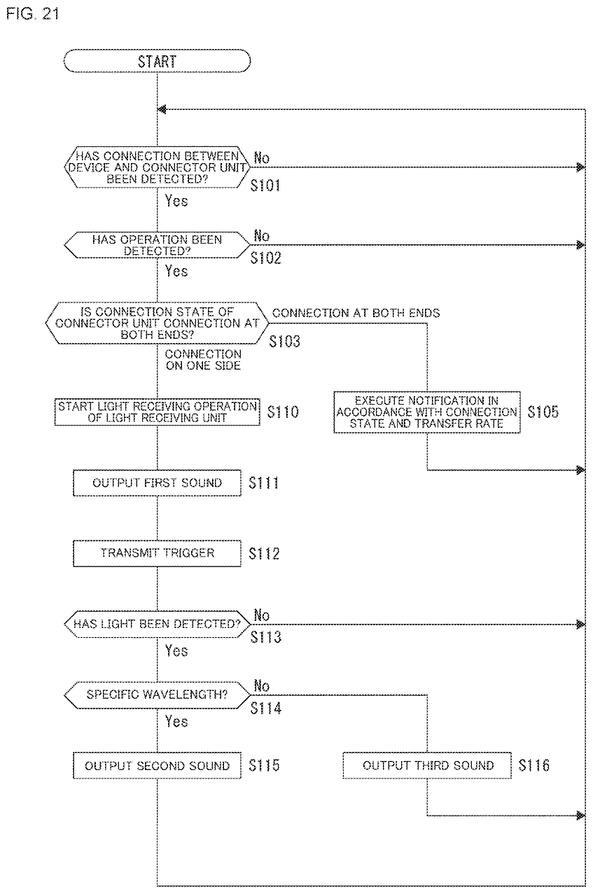

A flowchart for realizing the seventh notification mode will be described with reference to FIG. 21.

Also, the same processes as that of the flowchart described with reference to FIG. 16 will be denoted by the same reference numerals and the description thereof will be omitted as appropriate.

Further, in the seventh notification mode in the second embodiment, a case in which the notification of the first connector unit C1 is executed will be described as an example. That is, a case in which the first connector unit C1 executes the flowchart shown in FIG. 21 will be described.

By executing steps S101 and S102, the first connector unit C1 determines whether or not either the first connector unit C1 or the second connector unit C2 is connected to the device and whether or not the operation of the operator on the first connector unit C1 has been detected.

In the first connector unit C1, in a case in which it is detected that either the first connector unit C1 or the second connector unit C2 has been connected to the device and the first operation detection unit 5 of the first connector unit C1 has detected the operation of the operator, the process proceeds to step S103, and if not, the process returns to step S101.

In step S103, the first connector unit C1 executes a determination process in accordance with the connection states of the connector units. Specifically, it is determined whether both the first connector unit C1 and the second connector unit C2 are connected to the devices, or only one connector unit is connected to the device.

In a case in which both the first connector unit C1 and the second connector unit C2 are connected to the device 100 and the device 101, the first connector unit C1 executes the process of step S105. That is, the notification in accordance with the transfer rate is executed.

On the other hand, in a case in which only one of the first connector unit C1 and the second connector unit C2 is connected to the device, the first connector unit C1 proceeds to the process of step S110.

In a case in which the second connector unit C2 is connected to the device 101 and the first connector unit C1 is not connected to any device, the first connector unit C1 starts a light receiving operation of the first light receiving unit 14 in step S110.

The first notification unit 6 of the first connector unit C1 outputs a first sound in step S111. The first sound is, for example, a sound output for giving a notification that the first connector unit C1 has been switched to a guidance mode in which a notification for guiding the first connector unit C1 to be connected to the device 100 is performed.

Next, the first wireless transmitting unit 15 of the first connector unit C1 performs the trigger transmission using the first antenna 18. The transmitted trigger is received by the wireless receiving unit 110 using the antenna 111. As a result, the light emitting operations of the first light emitting unit 106, the second light emitting unit 107, the third light emitting unit 108, and the fourth light emitting unit 109 are started in the device 100.

Also, a reachable distance of the trigger transmitted from the first antenna 18 and the second antenna 19 may be a short distance. As a result, in a case in which the operator mistakenly performs an operation in a situation in which the connector unit is located far from the device 100 or the device 101, the trigger does not reach the device 100 or the device 101, so that an unnecessary light emitting operation is not performed. That is, it is possible to inhibit an increase in the power consumption of the device.

Subsequently, in step S113, the first connector unit C1 determines whether or not the first light receiving unit 14 has received light having a predetermined intensity or higher within a predetermined wavelength range (for example, light having a wavelength of 400 nm or more and less than 800 nm).

In a case in which the predetermined light is not received, the first connector unit C1 returns to the process of step S101. Further, in a case in which the process of step S102 is executed again after returning to step S101, if the operation of the operator continues to be detected, that is, if the mechanical switch serving as the first operation detection unit 5 is continuously pressed by the operator, each process of step S110, step S111 and step S112 may be omitted without being executed. As a result, it is possible to prevent the first sound from being repeatedly output and the trigger transmission for light emission from being performed.

Also, if the predetermined light is not detected in step S113, the process of step S113 may be repeated until the predetermined light is received.

After the predetermined light is detected, the first connector unit C1 determines in step S114 whether or not the received light is light of a specific wavelength. The light of the specific wavelength is predetermined in accordance with the standard of the cable 1 and shapes of connectors, and in the present example, assuming that the correct connection destination of the cable 1 is the first connection part 102, it will be a process of determining whether or not the wavelength of the received light is 700 nm (or its vicinity) in the process of step S114.

In a case in which the wavelength of the received light is the specific wavelength, the first notification unit 6 of the first connector unit C1 outputs a second sound in step S115. The second sound is a sound output when the connector unit is caused to face the correct connection part (first connection part 102), and is, for example, a success sound.

On the other hand, in a case in which the wavelength of the received light is other than the specific wavelength, for example, it is a wavelength of blue light, the first notification unit 6 of the first connector unit C1 outputs a third sound in step S116. The third sound is a sound output in a case in which the connector unit is caused to face an erroneous connection part (for example, the second connection part 103), and is, for example, a failure sound or a warning sound.

Also, the difference between the second sound and the third sound may be a difference in timbre, may be a difference in pitch, or may be a length of time during which the sound is output. Further, it may be a difference in output interval between sounds. Alternatively, it may be a voice message that can be heard by the operator. In any case, it is sufficient that the operator can identify that the second sound and the third sound are different sounds.

After any of the processes of step S115 and step S116 has been executed, the first connector unit C1 executes the process of step S101 again.

As a result, various sounds are output while the operator continues to press the mechanical switch serving as the first operation detection unit 5, and the operator's connection work can be assisted.

Also, the first wireless transmitting unit 15 of the first connector unit C1 uses the first antenna 18 to transmit the trigger in step S112, but at this time, information for specifying the wavelength of the light to be emitted, information for specifying the standard of the cable 1, or information for specifying the connector shape of the first connector unit C1 of the cable 1 may be transmitted to the device 100.

As a result, the device 100 can specify which standard the cable 1 has, or what kind of shape the connector of the first connector unit C1 has, and the connection part (for example, the first connection part 102) corresponding to the first connector unit C1 of the cable 1 can be specified.

Accordingly, since only the light emitting unit (first light emitting unit 106) corresponding to the specified connection part (first connection part 102) can emit light, it is possible to contribute to the reduction of the power consumption of the device 100.

Further, in that case, it is configured such that, in a case in which the first connector unit C1 is moved to face each connection part of the device 100 in order, the success sound (second sound) is output when it is located at a position facing the correct connection part (first connection part 102), and no sound is output when it is located at a position facing any other connection part. As a result, the operator can ascertain the correct position of the connection part and can improve the work efficiency.

Also, in this case, since the device 100 emits light only from the light emitting unit corresponding to the specific connection part, the first light receiving unit 14 does not receive the light from the light emitting unit corresponding to an erroneous connection part.

Accordingly, the first light receiving unit 14 of the first connector unit C1 does not need to be configured to receive only the specific wavelength, and the first connector unit C1 may determine in step S113 whether or not it has received some kind of light. That is, each process of step S114 and step S116 becomes unnecessary. Further, with such a configuration, it is not necessary for the device 100 to change the emission color for each connection part, and it is possible to configure all the light emitting units to emit light having the same wavelength. That is, it is possible to unify the light emitting components used in the light emitting unit, and it is possible to contribute to prevention of assembly mistakes and reduction of component costs.

### <4-3. Eighth Notification Mode>

An eighth notification mode is a notification mode in a case in which the first operation detection unit 5 detects the operation of the operator when the first connector unit C1 is connected to the device 100 from a free state in a state in which the second connector unit C2 has been connected to the device 101. Alternatively, it is a notification mode in a case in which the first connector unit C1 is connected to the device 100 in a state in which the first operation detection unit 5 has detected the operation of the operator. In other words, it is a notification mode performed after the first connector unit C1 is connected to the device 100.

As a result, for example, in the case of connecting cables with the same connector shape despite different standards, it is possible to notify the operator of whether or not appropriate connection work has been performed, and it is possible to improve work efficiency and reduce work mistakes.

### <4-4. Flowchart in Eighth Notification Mode>

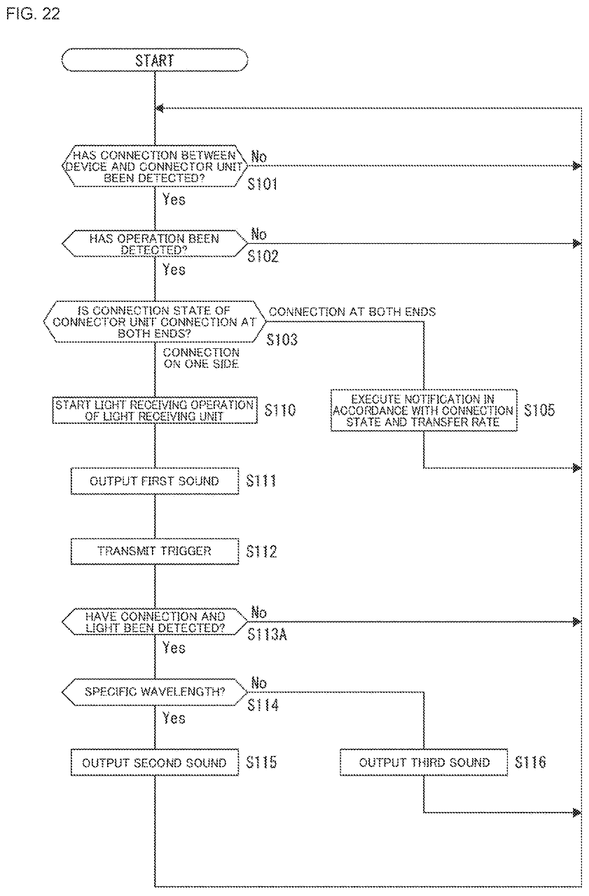

A flowchart for realizing an eighth notification mode will be described with reference to FIG. 22.

By executing the processes of steps S101, S102, S103, and S105, the first connector unit C1 caused the notification mode to be expressed in accordance with the transfer rate in a case in which both the first connector unit C1 and the second connector unit C2 are connected to the device 100 and the device 101. Of course, the notification mode may be expressed in accordance with a charge state, or the notification mode may be expressed in accordance with a connection state.

In a case in which it is determined in step S103 that only one of the connector units has been connected to the device, the first connector unit C1 executes the process of step S110.

In the present example, the first operation detection unit 5 detects the operation of the operator in a state in which the first connector unit C1 is free.

In this case, in the process of step S110, the light receiving operation of the first light receiving unit 14 provided in the first connector unit C1 is started.

Next, in step S111, the first connector unit C1 outputs the first sound using the first notification unit 6, and in step S112, performs the trigger transmission using the first wireless transmitting unit 15 and the first antenna 18.

Next, in step S113A, the first connector unit C1 performs the branch process based on whether or not the first connector unit C1 has detected the connection to the device 100 and the first light receiving unit 14 has detected the reception of light. In a case in which the first connector unit C1 has not detected the connection to the device 100, or the first light receiving unit 14 has not detected the reception of light, the first connector unit C1 returns to the process of step S101. Also, in a case in which the first operation detection unit 5 continues to detect the operation of the operator until the process returns to the process of step S101 and then the process of step S110 or step S111 or the process of step S112 is executed, the process of step S113A may proceed without performing the processes of step S110, step S111, and step S112.

Further, in a case in which the determination in step S113A is “No”, the process of step S113A may be repeated as long as the first operation detection unit 5 continues to detect the operation of the operator.

In a case in which the first connector unit C1 has been connected to the device 100 and the first light receiving unit 14 has detected the reception of light, the first connector unit C1 determines whether or not the light received by the first light receiving unit 14 has a specific wavelength in step S114, and if it is the specific wavelength, the process of step S115 is performed, and if it is not a specific wavelength, the process of step S116 is executed.

According to the eighth notification mode, in a case in which the first connector unit C1 has been connected to the connection part of the device 100, the notification sound (second sound or third sound) for giving a notification of whether or not the connection part is appropriate is output.

Even in such a notification mode, it is possible to notify the operator of whether or not an appropriate connection work has been performed, and it is possible to improve work efficiency and reduce work mistakes.

### 5. Modified Examples

In a case in which a proximity sensor is used as the first operation detection unit 5 or the second operation detection unit 8, each connector unit performs a notification operation of the notification unit on condition that approach of the operator's finger or the like has been detected. However, in a case in which the approaching finger does not move for a long time, the operation detection unit continues to detect the operation, and thus the notification operation of each notification unit is continued. In such a situation, in a case in which what is detected by the operation detection unit is not a finger of the operator but a false detection, unnecessary notification operations and the like are continued until the erroneous detection is canceled, and thus there is a risk of increasing power consumption.

Thus, after the operation detection of the operation detection unit, the notification operation or the like may be performed only for a certain period of time. As a result, when a certain time has elapsed after the operation was detected, the notification operation or the like is terminated, and thus an increase in power consumption can be inhibited. Further, in a case in which it is desired to cause the notification operation to be expressed again, the operator may perform an operation to cause the operation detection unit to perform a new detection, which does not unnecessarily increase a burden on the operator.

The above-mentioned notification operation is performed by each connector unit, but it may be performed in the entire cable 1. For example, in a case in which the notification unit is a sound output unit, the cable 1 may be configured such that sound is output not only from the connector unit but also from the cable unit 4. In a case in which the notification unit is a vibration generation unit, vibration generation units may be provided at various locations to vibrate the entire cable unit 4 in addition to the connector unit.

As a result, it is possible to reliably give a notification to the operator, thereby further improving the work efficiency.

Also, a configuration in which the notification operation is performed only by the cable unit 4 without performing the notification using the connector unit may be adopted. In that case, by disposing the notification unit at a position in the cable unit 4 near each connector unit, the same effect as in the case of performing the notification from the connector unit can be obtained.

In addition, in a case in which one of the connector units is in a free state and the vibration generation unit gives a notification, regardless of which operation detection unit detects the operation, the vibration generation unit provided in the free connector unit may generate vibration to perform the notification. As a result, the connector unit connected to the device does not become a source of vibration, and thus it is possible to prevent the connection part of the device and the connector unit of the cable 1 from being damaged or worn.

An example in which the notification of the place to which the connector unit is to be connected is performed by performing the light emitting operation of the light emitting unit corresponding to each connection part of the device has been described in the second embodiment, but in this case, the light emitting unit corresponding to the connection part to which the other connector unit is already connected may be configured not to emit light. As a result, it is possible to prevent the connector unit from accidentally being guided to the connection part to which another connector unit is already connected, and the connector unit targeted for the work this time cannot be connected. That is, the work efficiency can be improved. Further, since the predetermined light emitting unit does not emit light, it is possible to contribute to the reduction of power consumption and the extension of the life of the light emitting unit.

In the second embodiment described above, an example in which the light emitting unit is provided on the device side and the light receiving unit is provided on the connector unit side has been described, but a light emitting unit may be provided on the connector unit side. For example, the light receiving unit on the device side may receive the light emitted from the light emitting unit provided in the connector unit, and guidance in accordance with its wavelength (for example, guidance by outputting a success sound or a warning sound) may be performed.

When the operation detection unit (first operation detection unit 5 or second operation detection unit 8) provided in the connector unit detects an operation, the notification unit (first notification unit 6 or second notification unit 9) performs a notification operation to the operator, but various possibilities can be considered for the execution timing and period of the notification operation.

For example, a configuration in which, by executing the notification operation only while the operation is being detected, the notification operation is stopped immediately when the operation is not detected may be adopted.

Also, a configuration in which the notification operation is executed for a certain period of time (for example, 5 seconds) from the operation detection may be adopted. As a result, the operator can receive a predetermined notification without continuously pressing a button (when the operation detection unit is a mechanical switch), and thus the work efficiency can be improved.

Further, a configuration in which the notification operation is executed while the operation is being detected, and the notification operation may be executed for a certain period of time (for example, 5 seconds) even after the operation is no longer detected may be adopted. As a result, even in a case in which not only the notification can be received at a posture that is easy to operate, but the connection work is performed at a posture that makes it difficult to operate the connector unit, the notification operation continues for a certain period of time from a non-detection state of the operation, and thus the work efficiency can be improved.

In each of the above-mentioned examples, an example in which the first operation detection unit 5 is provided in the first connector unit C1 of the cable 1 and the second operation detection unit 8 is provided in the second connector unit C2 has been described, but the operation detection unit may not be provided in each connector unit of the cable 1.

For example, in a case in which the situation changes from a state in which both connector units are not connected to the devices to a state in which only the first connector unit C1 is connected to the device 100, the first notification unit 6 of the first connector unit C1 performs a light emitting operation to notify the operator that the second connector unit C2 is not connected.

Next, in a case in which the second connector unit C2 has been connected to the device 101, the light emitting operation of the first notification unit 6 of the first connector unit C1 is stopped.

As a result, the operator can determine whether or not the cable connection work has been completed by recognizing whether or not the first notification unit 6 is turned on, and thus the work efficiency can be improved. Further, since the operation detection unit is not provided in each connector unit, it is possible to reduce the man-hours for manufacturing the cable 1 and reduce costs by reducing the number of components.

In addition, a configuration in which, in a case in which the situation changes from the state in which both connector units are not connected to the devices to the state in which only the first connector unit C1 is connected to the device 100, the second notification unit 9 of the second connector unit C2 performs a light emitting operation may be adopted. This makes it possible to easily identify the second connector unit C2 corresponding to the connected first connector unit C1. In addition, in a case in which the second connector unit C2 is connected to the device 101, the light emitting operation of the second notification unit 9 of the second connector unit C2 is stopped.

Even with such a configuration, when the operator connects the light emitting second connector unit C2 to the device 101, the connection work is completed, and thus the work efficiency can be improved.

Also, similarly to the above, it is possible to reduce the man-hours for manufacturing the cable 1 and reduce the costs by reducing the number of components.

### 6. Summary

As described in each of the above examples, the cable 1 according to the present technique includes the first connector unit C1, the second connector unit C2, the transmission line 11 that has one end connected to the first connector unit C1 and the other end connected to the second connector unit C2, the control unit (first control unit 7 or second control unit 10) that detects connection states of the first connector unit C1 and the second connector unit C2, the operation detection unit (first operation detection unit 5 or second operation detection unit 8) that detects an operation on any one connector unit of the first connector unit C1 and the second connector unit C2, and the notification unit (first notification unit 6 or second notification unit 9) that performs a notification in accordance with the connection state of the other connector unit in accordance with detection results of the operation detection unit.

The connection state of the connector unit is, for example, a distinction of whether the connector unit has been connected to a device that is a connection target (a connection target device) (connection determination) or not (non-connection determination). In order to give a notification of the connection state, the cable according to the present technique deals with information (connection information) for specifying the connection state. The information may be, for example, detection signals or information obtained by a determination process.

By providing the notification unit for giving a notification of the connection state of the connector unit, the operator can correctly recognize a state of the cable. This prevents a wrong cable from being pulled out and a wrong cable from being connected. Further, in a situation in which the connector unit on the other end side cannot be visually recognized, a notification is provided so that the operator can ascertain the connection situation of the connector unit on the other end side which cannot be visually recognized, whereby it is possible to prevent unnecessary insertion and removal of the connector unit (for example, an act of accidentally disconnecting the adjacent cable) from mistakenly being performed, and the efficiency of connection work of the cable 1 can be improved.

Further, since the notification operation is performed while either one of the connector units has been connected, it is not necessary to perform the notification operation when neither the first connector unit C1 nor the second connector unit C2 is connected to the devices.

As a result, since it is possible to give a notification using the power supply from the devices, it is not necessary to mount a battery in the cable 1, which can contribute to reduction of the number of components of the cable 1, and reduction in size and cost.

As the operation detection unit, for example, a mechanical switch, a proximity sensor, a contact sensor, or the like is used. By providing the operation detection unit, the operation of the operator's cable 1 (or connector unit) is detected. As a result, the notification can be executed by the notification unit at the will of the operator. That is, the operator can operate to intentionally execute the notification, thereby ascertaining the connection state of the connector unit.

As described in each of the above examples, the control unit (first control unit 7 or second control unit 10) of the cable 1 according to the present technique may include the first connection detection unit (first control unit 7) that is provided in the first connector unit C1 and detects the connection state of the first connector unit C1, and the second connection detection unit (second control unit 10) that is provided in the second connector unit C2 and detects the connection state of the second connector unit C2.

By providing the first control unit 7 that detects whether or not the first connector unit C1 is connected to a device, it is possible to correctly ascertain the connection state of the first connector unit C1. Further, it is also possible to notify the second connector unit C2 of the connection state of the first connector unit C1 via the transmission line.

This makes it possible for the second connector unit C2 side to give a notification of the connection state of the first connector unit C1 side. Accordingly, for example, the operator who can visually recognize the connection state of the first connector unit C1 is notified of the connection state of the second connector unit C2, which makes it possible to ascertain the connection states of the connector units provided at both ends of the cable 1 from one of the connector units. That is, it is not necessary to specify the two corresponding (both ends) connector units provided at both ends of one cable 1 from among a large number of connector units, and it is possible to improve the work efficiency of connection work of the cable 1.

As described in each of the above examples, in the cable 1 according to the present technique, as the operation detection unit, the first operation detection unit 5 provided in the first connector unit C1 and the second operation detection unit 8 provided in the second connector unit C2 may be provided.

That is, the operation detection unit is provided in each of the first connector unit C1 and the second connector unit C2.

As a result, when one of the connector units can be operated, the operator can receive the information regarding the connection state to be notified.

As described in each of the above examples, in the cable 1 according to the present technique, the first operation detection unit 5 may detect the operation on the first connector unit C1, and the second operation detection unit 8 may detect the operation on the second connector unit C2.

An operated connector unit can be detected by the respective operation detection unit provided in the respective connector unit.

Accordingly, the operation of the operator can be detected without going through the transmission path 11.

As described in the first embodiment, in the cable 1 according to the present technique, in response to the event that any one operation detection unit of the first operation detection unit 5 and the second operation detection unit 8 has performed an operation detection, the notification unit (first notification unit 6 or second notification unit 9) may perform a notification in accordance with the connection state of the connector unit provided with the other operation detection unit. That is, in a case in which the first operation detection unit 5 has performed the operation detection in response to the event that the operator has performed the operation on the first connector unit C1, the notification of the connection state of the second connector unit C2 is performed.

Accordingly, the operator can ascertain the connection state of the second connector unit C2 at the other end only by operating the first connector unit C1, and thus it is not necessary to find the connector unit at the other end to check the connection state, and the efficiency of connection work of the cable 1 can be improved. The same applies to the case in which the operation for the second connector unit C2 is performed.

As described in each of the above examples, in the cable 1 according to the present technique, as the notification unit, the first notification unit 6 provided in the first connector unit C1 and the second notification unit 9 provided in the second connector unit C2 may be provided.

That is, the notification unit is provided in each of the connector units.

This makes it possible to receive the notification information from any connector unit, and thus it is easy to ascertain the connection states of the connector units.

As described in the second notification mode, the fourth notification mode, or the sixth notification mode, in the cable 1 according to the present technique, the first connector unit C1 may be provided with the first operation detection unit 5, the second connector unit C2 may be provided with the second operation detection unit 8, the first notification unit 6 may perform a notification in accordance with the connection state of the second connector unit C2 in response to the event that the first operation detection unit 5 has performed an operation detection, and the second notification unit 9 may perform a notification in accordance with the connection state of the first connector unit C1 in response to the event that the second operation detection unit 8 has performed an operation detection.

That is, for the operator who is in a state in which the operation on the first connector unit C1 is possible, the connection information of the second connector unit C2 on the other end side can be checked from the first notification unit 6 provided in the first connector unit C1.

As a result, an improvement in convenience can be achieved. In particular, even in a situation in which the situation of the second connector unit C2 on the other end side cannot be ascertained, if the operation for one connector unit (that is, the first connector unit C1) is possible, the connection states at both ends can be ascertained from the one connector unit. The same applies to the case in which the operation for the second connector unit C2 is possible and the state of the first connector unit C1 cannot be ascertained.

As described using the flowchart for the first embodiment, in the cable 1 according to the present technique, the notification unit (first notification unit 6 or second notification unit 9) may perform a notification according to a first mode in a case in which both of the first connector unit C1 and the second connector unit C2 are connected to devices and perform a notification according to a second mode in a case in which only one connector unit of the first connector unit C1 and the second connector unit C2 is connected to a device.

That is, the notification mode of the notification unit differs depending on whether or not both ends are connected.

As a result, it is possible to ascertain from the notification whether or not the cable 1 is in a usable state, for example, a state in which communication between two devices is possible by connecting the connector units at both ends to the devices. Further, a configuration in which, by performing the notification in different notification cycles in the first mode and the second mode, it is possible to ascertain whether or not both are connected may be adopted. For example, when the first notification unit 6 and the second notification unit 9 are notification light emitting units, it is also possible to shorten or lengthen the light emitting cycle depending on whether both are connected or only one is connected. Alternatively, even when the light emitting cycles of the first notification unit 6 and the second notification unit 9 are the same, whether or not both connector units are connected may be notified by whether or not the light emitting timing is shifted by half a cycle.

As described in the fifth notification mode and the sixth notification mode, in the cable 1 according to the present technique, the notification unit (first notification unit 6 or second notification unit 9) may perform a notification in accordance with the communication speed in communication of information performed via the transmission line 11 in a case in which both of the first connector unit C1 and the second connector unit C2 are connected to devices.

That is, by connecting the connector units at both ends to the devices, information other than the connection information is notified in a state in which information communication via the transmission line 11 is possible.

Specifically, the communication speed of information communication performed via the transmission line 11 is notified as information other than the connection information. As a result, for example, a state in which information communication is performed at a low speed with respect to the performance of the cable 1 since the cable 1 is erroneously connected can be ascertained from the notification, reinsertion of the cable 1 or the like can be performed. That is, finding a problem can be easier. In addition, it becomes possible to detect in advance a performance deterioration not intended by the operator.

As described in the fifth notification mode and the sixth notification mode, in the cable 1 according to the present technique, the notification unit (first notification unit 6 or second notification unit 9) may perform a notification in accordance with a charge amount of a charging target device in a case in which any one connector unit of the first connector unit C1 and the second connector unit C2 is connected to a charging device and the other connector unit is connected to the charging target device.

The charge amount indicates, for example, a proportion of a remaining amount of battery of the charging target device. In a state in which the charging target device and the charging device are correctly connected with each other, the notification in accordance with the charge amount of the charging target device is performed to the operator.

As a result, it is possible to ascertain the remaining amount of battery of the charging target device simply by operating the cable 1 (or the connector unit) without starting the charging target device and checking the remaining amount of battery, and it is possible to achieve an improvement in convenience.

As described in the second embodiment, the cable 1 according to the present technique may include the first light receiving unit 14 provided in the first connector unit C1, and in a case in which the second connector unit C2 is connected to a device and the first operation detection unit 5 has detected an operation, the notification unit (first notification unit 6 or second notification unit 9) may perform a notification in accordance with whether or not the first light receiving unit 14 has received light having a specific wavelength.

For example, in the device to which the cable 1 is connected, in a case in which a light emitting unit (the first light emitting unit 106, the second light emitting unit 107, the third light emitting unit 108, the fourth light emitting unit 109, and the like) that emits light having the specific wavelength is provided in the vicinity of a place at which the cable 1 is to be connected, the notification unit performs a notification in response to the event that the light having the specific wavelength has been received with a certain intensity or higher when the operator brings the first connector unit C1 of the cable 1 closer to the device.

As a result, the operator can find the place at which the cable 1 is to be inserted in response to the notification of the notification unit. That is, by giving a notification of whether or not the light having the specific wavelength has been received, the first connector unit C1 can be guided, and an improvement in convenience can be achieved. In addition, it is possible to prevent problems due to incorrect insertion. Also, the present configuration can be paraphrased as follows. For example, the cable 1 may include the first light receiving unit 14 provided in the first connector unit C1 and the second light receiving unit 16 provided on the second connector unit C2, with one of the first connector unit C1 and the second connector unit C2 connected to a device and the other connector unit not connected to a device, and in a case in which the operation detection unit provided on the other connector unit has detected an operation, the notification unit may perform a notification in accordance with whether or not a light receiving unit provided in the other connector unit of the first light receiving unit 14 and the second light receiving unit 16 has received the light having the specific wavelength.

As described in the second embodiment, in the cable 1 according to the present technique, the specific wavelength may be a wavelength corresponding to a type of connector.

By changing the specific wavelength for each type of connector, it is possible to provide the light emitting unit that emits the light having the specific wavelength corresponding to each connection place of each type of connector.

That is, since it is possible to perform guidance to different connection places for each cable type of the cable 1, it becomes easy to reduce the connection work and prevent erroneous connection for devices to which various cables 1 can be connected.

As described in the second embodiment, the cable 1 according to the present technique may include the first sound output unit (sound output unit serving as the first notification unit 6) provided in the first connector unit C1, and in a case in which the second connector unit C2 is connected to the device and the first operation detection unit 5 has detected an operation, the first sound output unit may output a sound for guiding the first connector unit C1 to a connection part (the first connection part 102 or the like).

By making the specific wavelength different for each type of connector, it is possible to specify the place at which the cable 1 is to be connected. Further, by providing the first voice output unit, voice guidance is performed even when connection work of the cable 1 is performed in a state in which the vicinity is not visible.

As a result, the efficiency of the connection work of the cable 1 can be improved regardless of the arrangement of the device and the cable 1. In addition, it is possible to prevent erroneous connection of the cable 1.

As described in the second embodiment, the cable 1 according to the present technique may include the first sound output unit (sound output unit serving as the first notification unit 6) provided in the first connector unit C1, and the first sound output unit may be configured to output a third sound (for example, a warning sound) in a case in which the first connector unit C1 comes closer to another connection unit (for example, the second connection unit 103) than a target connection part (for example, the first connection part 102).

That is, the first sound output unit notifies information regarding whether or not the first connector unit C1 is approaching a correct connection place.

Accordingly, the operator can ascertain the correct connection position of the cable 1, and the efficiency of the connection work can be further improved.

As described in the second embodiment, the cable 1 according to the present technique may include the first sound output unit (sound output unit serving as the first notification unit 6) provided in the first connector unit C1, and the first sound output unit may output a second sound (for example, a success sound) in a case in which the first connector unit C1 is connected to a target connection part.

As a result, information regarding whether or not the connection is correct is notified to the operator using a success sound in a case in which the first connector unit C1 is connected to the device.

That is, it is possible to prevent erroneous connection of the cable 1.

As described in the eighth notification mode, in the cable 1 according to the present technique, the notification unit (for example, the first notification unit 6) may perform a notification in a case in which the first connector unit C1 is connected to the device 100 and the first light receiving unit 14 receives light.

Even in such a notification mode, the operator is notified of whether or not appropriate connection work has been performed, and thus it is possible to prevent erroneous connection.

Further, in a case in which the first light receiving unit 14 has not received light, the notification operation is not performed, and thus it is possible to prevent an excessive notification from being performed.

As described in the first embodiment, in the cable 1 according to the present technique, the notification unit (first notification unit 6 or second notification unit 9) is a notification light emitting unit, and the notification may be performed using the light emission of the notification light emitting unit.

As a result, the connection states of the connector units are notified using the light emission.

Accordingly, since the operator can be reliably notified, for example, in a case in which the connection work is performed in the dark, it is possible to improve work efficiency and prevent erroneous connection.

As described in each of the above examples, particularly in the second embodiment, in the cable 1 according to the present technique, the notification unit (first notification unit 6 or second notification unit 9) may be assumed to have a sound output unit, and the notification may be performed using a sound output generated by the sound output unit.

As a result, the connection states of the connector units are notified using sound. Accordingly, appropriate notification can be performed, for example, in a case in which the connection work is performed in a situation in which a positional relationship between the device and the connector unit cannot be ascertained. In particular, by performing a notification in accordance with the positional relationship, for example, a notification such as “It is on a bit right side”, optimal notification can be performed, and work efficiency can be improved.

A notification method comprising, in the cable 1 including: the first connector unit C1; the second connector unit C2; the transmission line 11 that has one end connected to the first connector unit C1 and the other end connected to the second connector unit C2; the control unit (first control unit 7 or second control unit 10) that detects connection states of the first connector unit C1 and the second connector unit C2; and the operation detection unit (first operation detection unit 5 or second operation detection unit 8) that detects an operation on any one connector unit of the first connector unit C1 and the second connector unit C2, performing a notification in accordance with a connection state of the other connector unit in accordance with detection results of the operation detection unit.

Also, the effects described in the present specification are merely exemplary and other effects may be obtained.

### 7. Application Examples

The technique according to the present disclosure can be applied to various products. For example, the technique according to the present disclosure may be applied to an operating room system.

FIG. 22 is a diagram schematically showing an overall configuration of an operating room system 5100 to which the technique according to the present disclosure may be applied. Referring to FIG. 22, the operating room system 5100 is configured by connecting a group of devices provided in an operating room in a coordinated manner via an audiovisual controller (AV Controller) 5107 and an operating room control device 5109.

Various devices can be installed in the operating room. As an example, FIG. 22 shows various device groups 5101 for endoscopic surgery, a ceiling camera 5187 provided on a ceiling of the operating room to capture an operator's hand, an operation place camera 5189 provided on the ceiling of the operating room to capture the entire operating room, a plurality of display devices 5103A to 5103D, a recorder 5105, a patient bed 5183, and a lighting 5191.

Here, among these devices, the device groups 5101 belong to an endoscopic surgery system 5113, which will be described later, and include an endoscope, a display device that displays an image captured by the endoscope, and the like. Each device belonging to the endoscopic surgery system 5113 is also referred to as a medical device. On the other hand, the display devices 5103A to 5103D, the recorder 5105, the patient bed 5183, and the lighting 5191 are devices provided in the operating room, for example, separately from the endoscopic surgery system 5113. Each device that does not belong to the endoscopic surgery system 5113 is also referred to as a non-medical device. The audiovisual controller 5107 and/or the operating room control device 5109 controls operations of these medical devices and non-medical devices in cooperation with each other.

The audiovisual controller 5107 controls overall processing related to image display in the medical devices and non-medical devices. Specifically, among the devices included in the operating room system 5100, the device groups 5101, the ceiling camera 5187, and the operation place camera 5189 may be devices (hereinafter, also referred to as source devices) having a function of transmitting information to be displayed during surgery (hereinafter, also referred to as display information). Further, the display devices 5103A to 5103D may be devices for outputting the display information (hereinafter, also referred to as output destination devices). In addition, the recorder 5105 may be a device that belongs to both the source devices and the output destination devices. The audiovisual controller 5107 has a function of controlling operations of the source devices and the output destination devices, acquiring the display information from the source devices, and transmitting the display information to cause the output destination devices to display or record it. Also, the display information includes various images captured during surgery, various information related to surgery (for example, physical information of a patient, test results in the past, information on a surgical procedure, etc.), and the like.

Specifically, as the display information, information about images of a surgical part in the patient's body cavity captured by the endoscope may be transmitted from the device groups 5101 to the audiovisual controller 5107. Also, as the display information, information about images in the vicinity of the operator captured by the ceiling camera 5187 may be transmitted from the ceiling camera 5187. Also, as display information, information about images showing a state of the entire operating room captured by the operation place camera 5189 may be transmitted from the operation place camera 5189. In a case in which the operating room system 5100 has another device having an imaging function, the audiovisual controller 5107 may also acquire information about images captured by the other device from the other device as the display information.

Alternatively, for example, the information about these images captured in the past is recorded in the recorder 5105 by the audiovisual controller 5107. The audiovisual controller 5107 can acquire the information about the images captured in the past from the recorder 5105 as the display information. Also, various information about surgery may be recorded in advance in the recorder 5105.

The audiovisual controller 5107 causes at least one of the display devices 5103A to 5103D, which are the output destination devices, to display the acquired display information (that is, the images captured during surgery and various information about surgery). In the illustrated example, the display device 5103A is a display device suspended from and installed at the ceiling of the operating room, the display device 5103B is a display device installed on a wall surface of the operating room, the display device 5103C is a display device installed on a desk in the operating room, and the display device 5103D is a mobile device having a display function (for example, a tablet personal computer (PC)).

Also, although not shown in FIG. 22, the operating room system 5100 may include devices outside the operating room. The devices outside the operating room may be, for example, a server connected to a network constructed inside or outside a hospital, a PC used by medical staff, a projector installed in a conference room of the hospital, or the like. In a case in which such external devices are outside the hospital, the audiovisual controller 5107 can also display the display information on a display device of another hospital via a video conference system or the like for telemedicine.

The operating room control device 5109 controls overall processing other than the processing related to image display in the non-medical devices. For example, the operating room control device 5109 controls drive of the patient bed 5183, the ceiling camera 5187, the operation place camera 5189, and the lighting 5191.

The operating room system 5100 is provided with a centralized operation panel 5111, and a user can give an instruction about image display to the audiovisual controller 5107 and an instruction about operations of the non-medical devices to the operating room control device 5109 via the centralized operation panel 5111. The centralized operation panel 5111 is configured by providing a touch panel on a display surface of a display device.

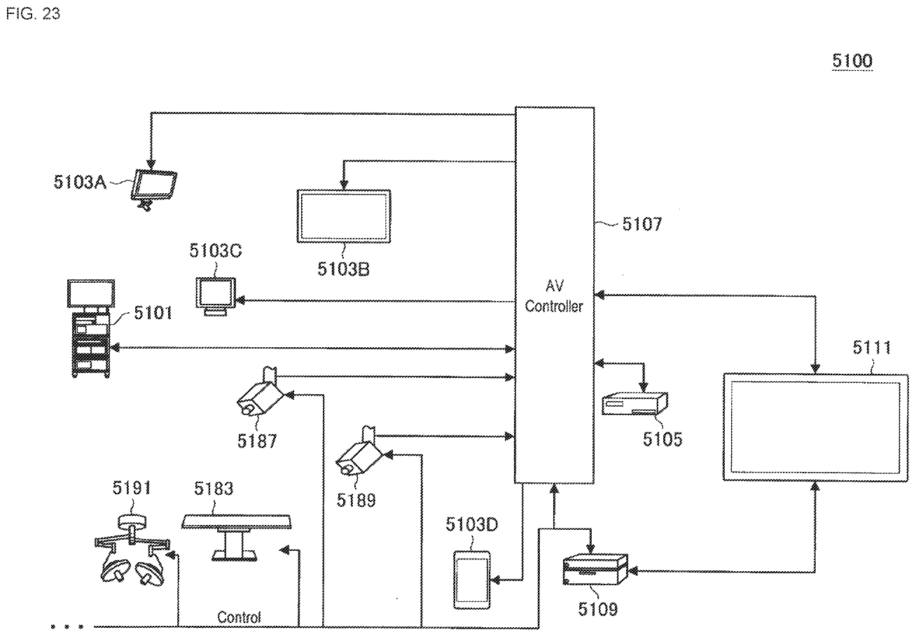

FIG. 23 is a diagram showing a display example of an operation screen on the centralized operation panel 5111. FIG. 23 shows, as an example, an operation screen corresponding to a case in which the operating room system 5100 is provided with two display devices as the output destination devices. Referring to FIG. 23, the operation screen 5193 is provided with a source selection area 5195, a preview area 5197, and a control area 5201.

In the source selection area 5195, the source devices provided in the operating room system 5100 and thumbnail screens showing the display information held by the source devices are linked and displayed. The user can select the display information to be displayed on a display device from any of the source devices displayed in the source selection area 5195.

In the preview area 5197, previews of screens displayed on the two display devices (Monitor 1 and Monitor 2), which are the output destination devices, are displayed. In the illustrated example, four images are picture-in-picture-displayed on one display device. The four images correspond to the display information transmitted from the source devices selected in the source selection area 5195. Among the four images, one is displayed relatively large as a main image and the remaining three are displayed relatively small as sub-images. The user can switch the main image and the sub images by appropriately selecting an area in which the four images are displayed. Further, a status display area 5199 is provided below the area in which the four images are displayed, and status related to surgery (for example, elapsed time of surgery, physical information of the patient, etc.) may be appropriately displayed in the area.

The control area 5201 is provided with a source operation area 5203 in which graphical user interface (GUI) components for operating the source devices are displayed and an output destination operation area 5205 in which the GUI components for performing operations on the output destination devices are displayed. In the illustrated example, the source operation area 5203 is provided with the GUI components for performing various operations (pan, tilt, and zoom) on cameras in the source devices having an imaging function. The user can operate operations of the cameras in the source devices by appropriately selecting these GUI components. Also, although not shown, in a case in which the source device selected in the source selection area 5195 is the recorder (that is, in a case in which an image recorded in the recorder in the past is displayed in the preview area 5197), the source operation area 5203 may be provided with GUI components for performing operations such as playing, stopping, rewinding, and fast-forwarding the image.

Further, the output destination operation area 5205 is provided with GUI components for performing various display operations (swap, flip, color adjustment, contrast adjustment, and switching between 2D display and 3D display) on display devices that are the output destination devices. The user can operate the display on the display devices by appropriately selecting these GUI components.

Also, the operation screens displayed on the centralized operation panel 5111 are not limited to the illustrated example, and the user may be able to input operations to each device provided in the operating room system 5100, which can be controlled by the audiovisual controller 5107 and the operating room control device 5109, via the centralized operation panel 5111.

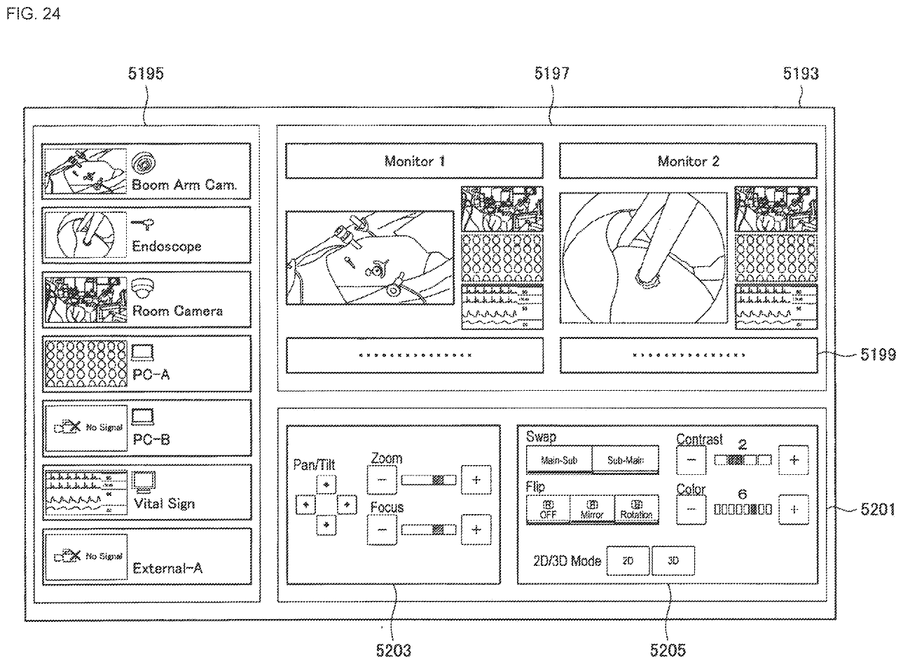

FIG. 24 is a diagram showing an example of a state of surgery to which the operating room system described above is applied. The ceiling camera 5187 and the operation place camera 5189 are provided on the ceiling of the operating room, and the vicinity of an operator (doctor) 5181 who performs treatment on an affected part of a patient 5185 on the patient bed 5183 and a state of the entire operating room can be captured. The ceiling camera 5187 and the operation place camera 5189 may have a magnification adjustment function, a focal length adjustment function, a photographing direction adjustment function, and the like. The lighting 5191 is provided on the ceiling of the operating room and illuminates at least the vicinity of the operator 5181. The lighting 5191 may be capable of appropriately adjusting an amount of irradiation light, a wavelength (color) of the irradiation light, an irradiation direction of the light, and the like.

As shown in FIG. 22, the endoscopic surgery system 5113, the patient bed 5183, the ceiling camera 5187, the operation place camera 5189, and the lighting 5191 are connected to each other in a coordinated manner via the audiovisual controller 5107 and the operating room control device 5109 (not shown in FIG. 24). The centralized operation panel 5111 is provided in the operating room, and as described above, the user can appropriately operate these devices present in the operating room via the centralized operation panel 5111.

Hereinafter, a configuration of the endoscopic surgery system 5113 will be described in detail. As illustrated, the endoscopic surgery system 5113 is configured of an endoscope 5115, other surgical tools 5131, a support arm device 5141 for supporting the endoscope 5115, and a cart 5151 equipped with various devices for endoscopic surgery.

In the endoscopic surgery, instead of cutting an abdominal wall to open the abdomen, a plurality of tubular laparotomy devices called trocars 5139a to 5139d are punctured into the abdominal wall. Then, from the trocars 5139a to 5139d, a lens barrel 5117 of the endoscope 5115 and other surgical tools 5131 are inserted into the body cavity of the patient 5185. In the illustrated example, as other surgical tools 5131, a pneumoperitoneum tube 5133, an energy treatment tool 5135, and forceps 5137 are inserted into the body cavity of patient 5185. Further, the energy treatment tool 5135 is a treatment tool that cuts and peels tissue, seals a blood vessel, or the like by using a high-frequency current or ultrasonic vibration. However, the illustrated surgical tools 5131 are only an exemplary, and as the surgical tools 5131, various surgical tools generally used in the endoscopic surgery such as a tweezer and a retractor may be used.

The images of the surgical part in the body cavity of the patient 5185 captured by the endoscope 5115 are displayed on a display device 5155. While viewing the images of the surgical part displayed on the display device 5155 in real time, the operator 5181 uses the energy treatment tool 5135 and the forceps 5137 to perform, for example, a treatment such as excising the affected area. Although not shown, the pneumoperitoneum tube 5133, the energy treatment tool 5135, and the forceps 5137 are supported by the operator 5181 or an assistant during surgery.

### (Support Arm Device)

The support arm device 5141 includes an arm portion 5145 extending from a base portion 5143. In the illustrated example, the arm portion 5145 is configured of joint portions 5147a, 5147b, and 5147c, and links 5149a and 5149b and is driven by control from the arm control device 5159. The endoscope 5115 is supported by the arm portion 5145, and its position and posture are controlled. As a result, a stable position of the endoscope 5115 can be fixed.

### (Endoscope)

The endoscope 5115 is configured of the lens barrel 5117 of which a region having a predetermined length from a tip is inserted into the body cavity of the patient 5185, and a camera head 5119 connected to a base end of the lens barrel 5117. In the illustrated example, the endoscope 5115 configured as a so-called rigid mirror having the rigid lens barrel 5117 is illustrated, but the endoscope 5115 may be configured as a so-called flexible mirror having the flexible lens barrel 5117.

An opening in which an objective lens is fitted is provided at the tip of the lens barrel 5117. A light source device 5157 is connected to the endoscope 5115, and light generated by the light source device 5157 is guided to the tip of the lens barrel by a light guide extending into the lens barrel 5117 and is radiated toward an observation target in the body cavity of the patient 5185 via the objective lens. Also, the endoscope 5115 may be a direct-viewing endoscope or may be a perspective endoscope or a side-viewing endoscope.

An optical system and an imaging element are provided inside the camera head 5119, and the reflected light (observation light) from the observation target is condensed on the imaging element by the optical system. The observation light is photoelectrically converted by the imaging element, and an electric signal corresponding to the observation light, that is, an image signal corresponding to an observed image is generated. The image signal is transmitted to a camera control unit (CCU) 5153 as RAW data. Also, the camera head 5119 has a function of appropriately driving the optical system to adjust a magnification and a focal length thereof.

Further, for example, the camera head 5119 may be provided with a plurality of imaging elements in order to support stereoscopic viewing (3D display) and the like. In this case, a plurality of relay optical systems are provided inside the lens barrel 5117 in order to guide the observation light to each of the plurality of imaging elements.

### (Various Devices Mounted on Cart)

The CCU 5153 includes, for example, a central processing unit (CPU) and a graphics processing unit (GPU), and generally controls operations of the endoscope 5115 and the display device 5155. Specifically, the CCU 5153 performs various image processing for displaying an image based on an image signal, such as development processing (demosaic processing), on the image signal received from the camera head 5119. The CCU 5153 provides the image signal subjected to the image processing to the display device 5155. In addition, the audiovisual controller 5107 shown in FIG. 22 is connected to the CCU 5153. The CCU 5153 also provides the image signal subjected to the image processing to the audiovisual controller 5107. Further, the CCU 5153 transmits a control signal to the camera head 5119 and controls drive thereof. The control signal may include information about imaging conditions such as a magnification and a focal length. The information regarding the imaging conditions may be input via an input device 5161 or may be input via the centralized operation panel 5111 described above.

The display device 5155 displays an image based on the image signal subjected to the image processing by the CCU 5153 under control of the CCU 5153. In a case in which the endoscope 5115 is for high-resolution photographing such as 4K (3840 horizontal pixels×2160 vertical pixels) or 8K (7680 horizontal pixels×4320 vertical pixels), and/or for 3D display, a device capable of displaying a high resolution and/or a device capable of displaying in 3D may be used corresponding to each as the display device 5155. In a case in which the display device is for high-resolution photographing such as 4K or 8K, a more immersive feeling can be obtained by using the display device 5155 having a size of 55 inches or more. Further, the plurality of display devices 5155 having different resolutions and sizes may be provided depending on applications.

The light source device 5157 is configured of a light source such as a light emitting diode (LED) and supplies the endoscope 5115 with irradiation light for imaging the surgical part or the like.

The arm control device 5159 is configured of, for example, a processor such as a CPU and controls drive of the arm portion 5145 of the support arm device 5141 in accordance with a predetermined control method by being operated by a predetermined program.

The input device 5161 is an input interface for the endoscopic surgery system 5113. The user can input various types of information or instructions to the endoscopic surgery system 5113 via the input device 5161. For example, the user inputs various information related to surgery, such as physical information of the patient and information about a surgical method via the input device 5161. Further, for example, the user inputs an instruction to drive the arm portion 5145, an instruction to change imaging conditions (types of irradiation light, magnification, focal length, etc.) for the endoscope 5115, an instruction to drive the energy treatment tool 5135, and the like via the input device 5161.

The type of the input device 5161 is not limited, and the input device 5161 may be various known input devices. As the input device 5161, for example, a mouse, a keyboard, a touch panel, a switch, a foot switch 5171 and/or a lever and the like can be adopted. In a case in which a touch panel is used as the input device 5161, the touch panel may be provided on a display surface of the display device 5155.

Alternatively, the input device 5161 is a device put on the user, such as a glasses-type wearable device or a head mounted display (HMD), and various inputs are made in accordance with the user's gesture and line of sight detected by these devices. Further, the input device 5161 includes a camera capable of detecting movement of the user, and various inputs are performed in accordance with the user's gesture and line of sight detected from images captured by the camera. Further, the input device 5161 includes a microphone capable of picking up the user's voice, and various inputs are performed by means of voice through the microphone. In this way, the input device 5161 is configured to be able to input various information in a non-contact manner, so that the user particularly in a clean area (for example, the operator 5181) can operate a device in a dirty area in a non-contact manner. In addition, the user can operate the device without taking his/her hand off the surgical tools that he/she has, which improves the convenience for the user.

A treatment tool control device 5163 controls drive of the energy treatment tool 5135 for cauterizing or incising tissue, sealing a blood vessel, or the like. A pneumoperitoneum device 5165 sends a gas into the body cavity through the pneumoperitoneum tube 5133 in order to inflate the body cavity of the patient 5185 for the purpose of securing a visual field for the endoscope 5115 and a working space for the operator. A recorder 5167 is a device capable of recording various information about surgery. A printer 5169 is a device capable of printing various information about surgery in various formats such as text, images, and graphs.

Hereinafter, a particularly characteristic configuration of the endoscopic surgery system 5113 will be described in more detail.

### (Support Arm Device)

The support arm device 5141 includes the base portion 5143 that is a base, and the arm portion 5145 that extends from the base portion 5143. In the illustrated example, the arm portion 5145 is configured of the plurality of joint portions 5147a, 5147b, and 5147c, and the plurality of links 5149a and 5149b connected by the joint portions 5147b, but in FIG. 24, for the sake of simplicity, the configuration of the arm portion 5145 is shown in a simplified manner. In reality, shapes, numbers and arrangements of the joint portions 5147a to 5147c and the links 5149a and 5149b, and directions of rotation axes of the joint portions 5147a to 5147c can be appropriately set so that the arm portion 5145 has desired degrees of freedom. For example, the arm portion 5145 can be preferably configured to have at least 6 degrees of freedom. As a result, since the endoscope 5115 can be freely moved within a movable range of the arm portion 5145, the lens barrel 5117 of the endoscope 5115 can be inserted into the body cavity of the patient 5185 in a desired direction.

Actuators are provided at the joint portions 5147a to 5147c, and the joint portions 5147a to 5147c are configured to be rotatable around predetermined rotation axes by driving the actuators. By controlling drive of the actuators using the arm control device 5159, the rotation angles of the joint portions 5147a to 5147c are controlled, and drive of the arm portion 5145 is controlled. As a result, control of the position and the posture of the endoscope 5115 can be realized. In this case, the arm control device 5159 can control the drive of the arm portion 5145 using various known control methods such as force control or position control.

For example, the operator 5181 may appropriately input an operation via the input device 5161 (including the foot switch 5171) to appropriately control the drive of the arm portion 5145 using the arm control device 5159 in accordance with the operation input, thereby controlling the position and the posture of the endoscope 5115. With this control, the endoscope 5115 at the tip of the arm portion 5145 can be moved from one arbitrary position to another arbitrary position, and then fixedly supported at the moved position. Also, the arm portion 5145 may be operated using a so-called master-slave method. In this case, the arm portion 5145 can be remotely controlled by the user via an input device 5161 installed at a place away from the operating room.

Further, in the case in which force control is applied, the arm control device 5159 may perform so-called power assist control in which the actuators of the joint portions 5147a to 5147c are driven to receive an external force from the user and the arm portion 5145 moves smoothly in accordance with the external force. As a result, when the user moves the arm portion 5145 while directly touching the arm portion 5145, the arm portion 5145 can be moved using a relatively light force. Accordingly, the endoscope 5115 can be moved more intuitively with a simpler operation, and thus convenience for the user can be improved.

Here, conventionally in the endoscopic surgery, the endoscope 5115 was supported by a doctor called a scopist. On the other hand, by using the support arm device 5141, it is possible to fix the position of the endoscope 5115 more reliably without manual work, and thus the images of the surgical part can be stably obtained, and the surgery can be smoothly performed.

Also, the arm control device 5159 does not necessarily have to be provided on the cart 5151. Further, the arm control device 5159 does not necessarily have to be one device. For example, the arm control device 5159 may be provided at each of the joint portions 5147a to 5147c of the arm portion 5145 of the support arm device 5141, or drive control of the arm portion 5145 may be realized by the cooperation of the plurality of arm control devices 5159 with each other.

### (Light Source Device)

The light source device 5157 supplies the endoscope 5115 with the irradiation light for photographing the surgical part. The light source device 5157 is configured of, for example, an LED, a laser light source, or a white light source configured of a combination thereof. At this time, in a case in which a white light source is configured by a combination of RGB laser light sources, the output intensity and output timing of each color (each wavelength) can be controlled with high accuracy, and thus the white balance of captured images can be adjusted by the light source device 5157. Further, in this case, the observation target is time-divisionally irradiated with laser light from the respective RGB laser light sources, and drive of an imaging element of the camera head 5119 is controlled in synchronization with the irradiation timing, so that the images corresponding to the respective RGB can be time-divisionally captured. According to this method, it is possible to obtain a color image without providing a color filter to the imaging element.

Further, the drive of the light source device 5157 may be controlled such that the intensity of the output light is changed at a predetermined time interval. The drive of the imaging element of the camera head 5119 is controlled in synchronization with the timing of the change of the light intensity to time-divisionally acquire images, and an image having a high dynamic range without so-called blackout and whiteout can be generated by combining the images.

Further, the light source device 5157 may be configured to be able to supply light having a predetermined wavelength band corresponding to special light observation. In the special light observation, for example, so-called narrow band light observation (narrow band imaging) in which predetermined tissue such as a blood vessel on a surface layer of a mucous membrane is photographed with high contrast by irradiating light having a narrower band than irradiation light (that is, white light) during normal observation using wavelength dependence of light absorption in body tissue is performed. Alternatively, in the special light observation, fluorescence observation in which an image is obtained using fluorescence generated by irradiation with excitation light may be performed. In the fluorescence observation, processes such as irradiating body tissue with excitation light and observing fluorescence from the body tissue (autofluorescence observation), or locally injecting a reagent such as indocyanine green (ICG) into the body tissue and irradiating the body tissue with excitation light corresponding to a fluorescence wavelength of the reagent to obtain a fluorescence image may be performed. The light source device 5157 may be configured to be able to supply narrow band light and/or the excitation light in accordance with such special light observation.

### (Camera Head and CCU)

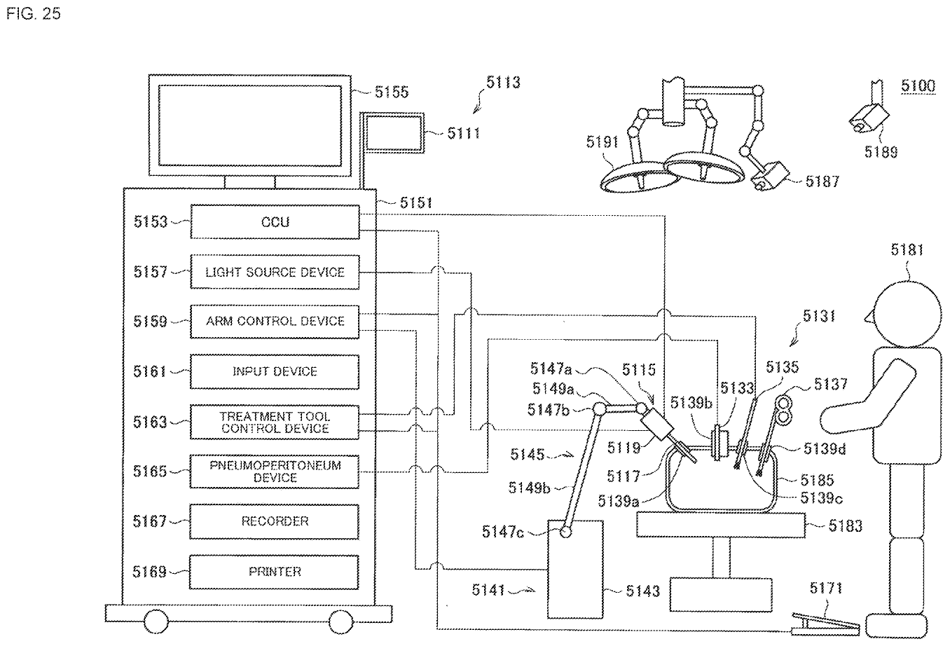

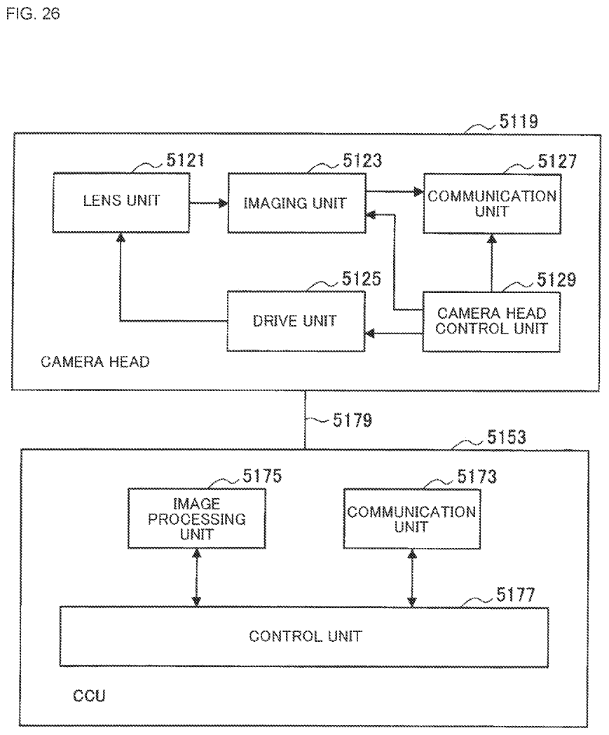

With reference to FIG. 25, functions of the camera head 5119 and the CCU 5153 of the endoscope 5115 will be described in more detail. FIG. 25 is a block diagram showing an example of a functional configuration of the camera head 5119 and CCU 5153 shown in FIG. 24.

Referring to FIG. 25, the camera head 5119 has, as functions thereof, a lens unit 5121, an imaging unit 5123, a drive unit 5125, a communication unit 5127, and a camera head control unit 5129. Further, the CCU 5153 has, as functions thereof, a communication unit 5173, an image processing unit 5175, and a control unit 5177. The camera head 5119 and the CCU 5153 are communicably connected to each other via a transmission cable 5179 in a bidirectional manner.

First, a functional configuration of the camera head 5119 will be described. The lens unit 5121 is an optical system provided at a connection portion with the lens barrel 5117. The observation light taken in from the tip of the lens barrel 5117 is guided to the camera head 5119 and incident on the lens unit 5121. The lens unit 5121 is configured of a combination of a plurality of lenses including a zoom lens and a focus lens. Optical characteristics of the lens unit 5121 are adjusted to collect the observation light on a light receiving surface of an imaging element of the imaging unit 5123. Further, the zoom lens and the focus lens are configured such that their positions on an optical axis can be moved in order to adjust a magnification and a focal point of a captured image.

The imaging unit 5123 is configured of an imaging element and is disposed at the latter stage of the lens unit 5121. The observation light that has passed through the lens unit 5121 is condensed on a light receiving surface of the imaging element, and an image signal corresponding to the observed image is generated by photoelectric conversion. The image signal generated by the imaging unit 5123 is provided to the communication unit 5127.

For the imaging element constituting the imaging unit 5123, for example, a complementary metal oxide semiconductor (CMOS) type image sensor having a Bayer array and capable of color photographing can be used. Also, for the imaging element, for example, an imaging element capable of photographing a high-resolution image of 4K or higher may be used. By obtaining the image of the surgical part with high resolution, the operator 5181 can ascertain the state of the surgical part in more detail, and surgery can proceed more smoothly.

Further, the imaging element constituting the imaging unit 5123 is configured to have a pair of imaging elements for acquiring image signals for the right eye and the left eye corresponding to 3D display. The 3D display is performed so that the operator 5181 can more accurately ascertain a depth of living tissue in the surgical part. Also, in a case in which the imaging unit 5123 is configured to be a multi-plate type, a plurality of groups of lens units 5121 may be provided to correspond to the respective imaging elements.

Further, the imaging unit 5123 does not necessarily have to be provided on the camera head 5119. For example, the imaging unit 5123 may be provided immediately after an objective lens inside the lens barrel 5117.

The drive unit 5125 is configured of an actuator and moves the zoom lens and the focus lens of the lens unit 5121 by a predetermined distance along the optical axis under the control of the camera head control unit 5129. As a result, the magnification and focus of the image captured by the imaging unit 5123 can be adjusted appropriately.

The communication unit 5127 is configured of a communication device for transmitting or receiving various pieces of information to or from the CCU 5153. The communication unit 5127 transmits an image signal obtained from the imaging unit 5123 as RAW data to the CCU 5153 via the transmission cable 5179. At this time, in order to display the captured image of the surgical part with low latency, the image signal is preferably transmitted through optical communication. This is because the operator 5181 performs surgery while observing a state of the affected area in the captured image at the time of surgery and it is required to display a video of the surgical part in real time as much as possible for safer and more reliable surgery. In a case in which optical communication is performed, the communication unit 5127 is provided with a photoelectric conversion module that converts an electric signal into an optical signal. The image signal is converted into an optical signal by the photoelectric conversion module and then transmitted to the CCU 5153 via the transmission cable 5179.

The communication unit 5127 also receives a control signal for controlling the drive of the camera head 5119 from the CCU 5153. The control signal includes, for example, information about imaging conditions such as information to specify a frame rate of a captured image, information to specify an exposure value at the time of imaging, and/or information to specify a magnification and a focal point of the captured image, etc. The communication unit 5127 provides the received control signal to the camera head control unit 5129. Also, the control signal from the CCU 5153 may be transmitted through optical communication. In this case, the communication unit 5127 is provided with a photoelectric conversion module that converts an optical signal into an electric signal, and the control signal is converted into an electric signal by the photoelectric conversion module and then provided to the camera head control unit 5129.

Further, the above imaging conditions such as the frame rate, the exposure value, the magnification, and the focal point are automatically set by the control unit 5177 of the CCU 5153 on the basis of the acquired image signal. That is, a so-called auto exposure (AE) function, an auto focus (AF) function, and an auto white balance (AWB) function are incorporated in the endoscope 5115.

The camera head control unit 5129 controls the drive of the camera head 5119 on the basis of the control signal from the CCU 5153 received via the communication unit 5127. For example, the camera head control unit 5129 controls drive of the imaging element of the imaging unit 5123 on the basis of the information to specify the frame rate of the captured image and/or the information to specify the exposure at the time of imaging. Further, for example, the camera head control unit 5129 appropriately moves the zoom lens and the focus lens of the lens unit 5121 via the drive unit 5125 on the basis of the information to specify the magnification and the focal point of the captured image. The camera head control unit 5129 may further have a function of storing information for identifying the lens barrel 5117 and the camera head 5119.

Also, by disposing the configuration of the lens unit 5121, the imaging unit 5123, and the like in a sealed structure with high airtightness and waterproofness, the camera head 5119 can be made resistant to autoclave sterilization processing.

Next, a functional configuration of the CCU 5153 will be described. The communication unit 5173 is configured of a communication device for transmitting and receiving various pieces of information to and from the camera head 5119. The communication unit 5173 receives an image signal transmitted from the camera head 5119 via the transmission cable 5179. At this time, as described above, the image signal can be suitably transmitted through optical communication. In this case, for the optical communication, the communication unit 5173 is provided with a photoelectric conversion module that converts an optical signal into an electric signal. The communication unit 5173 provides the image signal converted into the electric signal to the image processing unit 5175.

Further, the communication unit 5173 transmits a control signal for controlling the drive of the camera head 5119 to the camera head 5119. The control signal may also be transmitted through optical communication.

The image processing unit 5175 performs various image processing on the image signal that is the RAW data transmitted from the camera head 5119. The image processing includes various known signal processing, for example, development processing, high image quality processing (band enhancement processing, super-resolution processing, noise reduction (NR) processing and/or camera shake correction processing, etc.), and/or enlargement processing (electronic zoom processing), etc. In addition, the image processing unit 5175 performs detection processing on the image signal for performing AE, AF, and AWB.

The image processing unit 5175 is configured of processors such as a CPU and GPU, and the above-mentioned image processing and detection processing may be performed by the processors being operated in accordance with a predetermined program. Further, in a case in which the image processing unit 5175 is configured of a plurality of GPUs, the image processing unit 5175 appropriately divides information related to the image signal and performs image processing in parallel using the plurality of GPUs.

The control unit 5177 performs various controls regarding imaging of the surgical part using the endoscope 5115 and displaying of the captured image. For example, the control unit 5177 generates a control signal for controlling the drive of the camera head 5119. In this case, in a case in which imaging conditions are input by the user, the control unit 5177 generates the control signal on the basis of the input of the user. Alternatively, in a case in which the AE function, the AF function, and the AWB function are incorporated into the endoscope 5115, the control unit 5177 appropriately calculates the optimum exposure value, a focal length, and white balance, and generates the control signal in accordance with results of detection processing performed by the image processing unit 5175.

Further, the control unit 5177 causes the display device 5155 to display the image of the surgical part on the basis of the image signal subjected to the image processing performed by the image processing unit 5175. In this case, the control unit 5177 recognizes various objects in the image of the surgical part using various image recognition techniques. For example, by detecting a shape, color, or the like of an edge of an object included in the image of the surgical part, the control unit 5177 can recognize surgical tools such as forceps, specific biological parts, bleeding, mist at the time of using the energy treatment tool 5135, and the like. When the control unit 5177 causes the display device 5155 to display the image of the surgical part, it may cause various types of surgical support information to be superimposed and displayed on the image of the surgical part using the results of recognition. By superimposing the surgical support information and presenting it to the operator 5181, it is possible to proceed with the surgery more safely and surely.

The transmission cable 5179 that connects the camera head 5119 with the CCU 5153 is an electric signal cable that supports electric signal communication, an optical fiber that supports optical communication, or a composite cable thereof.

Here, in the illustrated example, wired communication is performed using the transmission cable 5179, but the communication between the camera head 5119 and the CCU 5153 may be performed wirelessly. In a case in which the communication between the two is performed wirelessly, there is no need to lay the transmission cable 5179 in the operating room, and thus a situation in which movements of medical staff in the operating room are hindered by the transmission cable 5179 may be eliminated.

The example of the operating room system 5100 to which the technique according to the present disclosure may be applied has been described above. Also, although the case in which a medical system to which the operating room system 5100 is applied is the endoscopic surgery system 5113 has been described here as an example, the configuration of the operating room system 5100 is not limited to such an example. For example, the operating room system 5100 may be applied to a flexible endoscopic system for examination or a microsurgery system instead of the endoscopic surgery system 5113.

The technique according to the present disclosure can be appropriately applied to the transmission cable 5179 among the configurations described in the above application examples. Specifically, in the operating room in which the camera head unit, the monitors, the recorder, and the like are connected to the CCU, by providing each function as the cable 1 described above in each cable used for connecting these devices with each other, it is possible to determine which device the connector units of the cable are being connected to.

Also, in a case in which the devices are connected to the CCU with the same type of cables, connection states of respective cables to the devices can be determined. In addition, it is possible to guide connection of an appropriate cable even in the same type of cables in accordance with information about the devices such as the transfer rate.

Further, in a case in which a plurality of monitors or the like are connected to the CCU, it is possible to guide the user so that an appropriate cable corresponding to each monitor is used in accordance with information about the devices such as the transfer rate.

### 8. Present Technique

The present technique can also adopt the following configurations.

(1)

A cable including:

a first connector unit;
a second connector unit;
a transmission line that has one end connected to the first connector unit and the other end connected to the second connector unit;
a control unit that detects connection states of the first connector unit and the second connector unit;
an operation detection unit that detects an operation on any one connector unit of the first connector unit and the second connector unit; and
a notification unit that performs a notification in accordance with the connection state of the other connector unit of the first connector unit and the second connector unit in accordance with detection results of the operation detection unit.
(2)

The cable according to the above (1), wherein

the control unit includes a first connection detection unit that is provided in the first connector unit and detects the connection state of the first connector unit, and a second connection detection unit that is provided in the second connector unit and detects the connection state of the second connector unit.
(3)

The cable according to the above (1), wherein as the operation detection unit, a first operation detection unit provided in the first connector unit and a second operation detection unit provided in the second connector unit are provided.

(4)

The cable according to the above (3), wherein

the first operation detection unit detects an operation on the first connector unit, and
the second operation detection unit detects an operation on the second connector unit.
(5)

The cable according to the above (4), wherein in response to the event that any one operation detection unit of the first operation detection unit and the second operation detection unit has performed an operation detection, the notification unit performs a notification in accordance with the connection state of the connector unit provided with the other operation detection unit.

(6)

The cable according to any one of the above (1) to (5), wherein as the notification unit, a first notification unit provided in the first connector unit and a second notification unit provided in the second connector unit are provided.

(7)

The cable according to any one of the above (6), wherein

the first connector unit is provided with the first operation detection unit,
the second connector unit is provided with the second operation detection unit, the first notification unit performs a notification in accordance with the connection state of the second connector unit in response to the event that the first operation detection unit has performed an operation detection, and
the second notification unit performs a notification in accordance with the connection state of the first connector unit in response to the event that the second operation detection unit has performed an operation detection.
(8)

The cable according to any one of the above (1) to (7), wherein the notification unit performs a notification according to a first mode in a case in which both of the first connector unit and the second connector unit are connected to devices and performs a notification according to a second mode in a case in which only one of the first connector unit and the second connector unit is connected to a device.

(9)

The cable according to any one of the above (1) to (8), wherein the notification unit performs a notification in accordance with a communication speed in communication of information performed via the transmission line in a case in which both of the first connector unit and the second connector unit are connected to a device.

(10)

The cable according to any one of the above (1) to (9), wherein the notification unit performs a notification in accordance with a charge amount of a charging target device in a case in which any one connector unit of the first connector unit and the second connector unit is connected to a charging device and the other connector unit is connected to the charging target device.

(11)

The cable according to any one of the above (3), (4), (5), and (7), further including a first light receiving unit provided in the first connector unit, wherein in a case in which the second connector unit is connected to a device and the first operation detection unit has detected an operation, the notification unit performs a notification in accordance with whether or not the first light receiving unit has received light having a specific wavelength.

(12)

The cable according to the above (11), wherein the specific wavelength is a wavelength corresponding to a type of connector.

(13)

The cable according to the above (12), further including a first sound output unit provided in the first connector unit, wherein in a case in which the second connector unit is connected to the device and the first operation detection unit has detected an operation, the first sound output unit outputs a sound for guiding the first connector unit to a connection part.

(14)

The cable according to the above (12) or (13), further including a first sound output unit provided in the first connector unit, wherein the first sound output unit outputs a third sound in a case in which the first connector unit comes closer to another connection part than to a target connection part.

(15)

The cable according to any one of the above (12) to (14), further including a first sound output unit provided in the first connector unit, wherein the first sound output unit outputs a second sound in a case in which the first connector unit is connected to a target connection part.

(16)

The cable according to any one of the above (11) to (15), wherein the notification unit performs a notification in a case in which the first connector unit is connected to the device and the first light receiving unit receives light.

(17)

The cable according to any one of the above (1) to (16), wherein the notification unit is a notification light emitting unit, and the notification is performed using light emission of the notification light emitting unit.

(18)

The cable according to any one of the above (1) to (16), wherein

the notification unit has a sound output unit, and
the notification is performed using a sound output generated by the sound output unit.
(19)

A notification method including, in a cable including: a first connector unit; a second connector unit; a transmission line that has one end connected to the first connector unit and the other end connected to the second connector unit; a control unit that detects connection states of the first connector unit and the second connector unit; and an operation detection unit that detects an operation on any one connector unit of the first connector unit and the second connector unit,

performing a notification in accordance with a connection state of the other connector unit in accordance with detection results of the operation detection unit.

### REFERENCE SIGNS LIST

1 Cable
C1 First connector unit
C2 Second connector unit
5 First operation detection unit
6 First notification unit
7 First connection detection unit
8 Second operation detection unit
9 Second notification unit
10 Second connection detection unit
11 Transmission line
14 First light receiving unit
100 Device
101 Device

1. A cable comprising:
a first connector unit;
a second connector unit;
a transmission line that has one end connected to the first connector unit and the other end connected to the second connector unit;
a control unit that detects connection states of the first connector unit and the second connector unit;
an operation detection unit that detects an operation on any one connector unit of the first connector unit and the second connector unit; and
a notification unit that performs a notification in accordance with the connection state of the other connector unit in accordance with detection results of the operation detection unit.

2. The cable according to claim 1, wherein
the control unit includes a first connection detection unit that is provided in the first connector unit and detects the connection state of the first connector unit, and a second connection detection unit that is provided in the second connector unit and detects the connection state of the second connector unit.

3. The cable according to claim 1, wherein as the operation detection unit, a first operation detection unit provided in the first connector unit and a second operation detection unit provided in the second connector unit are provided.

4. The cable according to claim 3, wherein
the first operation detection unit detects an operation on the first connector unit, and
the second operation detection unit detects an operation on the second connector unit.

5. The cable according to claim 4, wherein in response to the event that any one operation detection unit of the first operation detection unit and the second operation detection unit has performed an operation detection, the notification unit performs a notification in accordance with the connection state of the connector unit provided with the other operation detection unit.

6. The cable according to claim 1, wherein as the notification unit, a first notification unit provided in the first connector unit and a second notification unit provided in the second connector unit are provided.

7. The cable according to claim 6, wherein
the first connector unit is provided with the first operation detection unit,
the second connector unit is provided with the second operation detection unit,
the first notification unit performs a notification in accordance with the connection state of the second connector unit in response to the event that the first operation detection unit has performed an operation detection, and
the second notification unit performs a notification in accordance with the connection state of the first connector unit in response to the event that the second operation detection unit has performed an operation detection.

8. The cable according to claim 1, wherein the notification unit performs a notification according to a first mode in a case in which both of the first connector unit and the second connector unit are connected to devices and perform a notification according to a second mode in a case in which only one connector unit of the first connector unit and the second connector unit is connected to a device.

9. The cable according to claim 1, wherein the notification unit performs a notification in accordance with a communication speed in communication of information performed via the transmission line in a case in which both of the first connector unit and the second connector unit are connected to devices.

10. The cable according to claim 1, wherein the notification unit performs a notification in accordance with a charge amount of a charging target device in a case in which any one connector unit of the first connector unit and the second connector unit is connected to a charging device and the other connector unit is connected to the charging target device.

11. The cable according to claim 3, further comprising a first light receiving unit provided in the first connector unit, wherein in a case in which the second connector unit is connected to a device and the first operation detection unit has detected an operation, the notification unit performs a notification in accordance with whether or not the first light receiving unit has received light having a specific wavelength.

12. The cable according to claim 11, wherein the specific wavelength is a wavelength corresponding to a type of connector.

13. The cable according to claim 12, further comprising a first sound output unit provided in the first connector unit, wherein in a case in which the second connector unit is connected to the device and the first operation detection unit has detected an operation, the first sound output unit outputs a sound for guiding the first connector unit to a connection part.

14. The cable according to claim 12, further comprising a first sound output unit provided in the first connector unit, wherein the first sound output unit outputs a third sound in a case in which the first connector unit comes closer to another connection part than to a target connection part.

15. The cable according to claim 12, further comprising a first sound output unit provided in the first connector unit, wherein the first sound output unit outputs a second sound in a case in which the first connector unit is connected to a target connection part.

16. The cable according to claim 11, wherein the notification unit performs a notification in a case in which the first connector unit is connected to the device and the first light receiving unit receives light.

17. The cable according to claim 1, wherein
the notification unit is a notification light emitting unit, and
the notification is performed using light emission of the notification light emitting unit.

18. The cable according to claim 1, wherein
the notification unit has a sound output unit, and
the notification is performed using a sound output generated by the sound output unit.

19. A notification method comprising, in a cable including: a first connector unit; a second connector unit; a transmission line that has one end connected to the first connector unit and the other end connected to the second connector unit; a control unit that detects connection states of the first connector unit and the second connector unit; and an operation detection unit that detects an operation on any one connector unit of the first connector unit and the second connector unit, performing a notification in accordance with a connection state of the other connector unit in accordance with detection results of the operation detection unit.
